(19) United States
(12) Patent Application Publication
(10) Pub. No.: US 2024/0249779 A1
(43) Pub. Date: Jul. 25, 2024

(54) STORAGE DEVICE AND OPERATING METHOD OF THE STORAGE DEVICE

(71) Applicant: Samsung Electronics Co., Ltd., Suwon-si (KR)

(72) Inventors: Minho Kim, Suwon-si (KR); Sooyoung Ji, Suwon-si (KR); Sanghwa Jin, Suwon-si (KR)

(21) Appl. No.: 18/528,875

(22) Filed: Dec. 5, 2023

(30) Foreign Application Priority Data
Jan. 19, 2023 (KR) 10-2023-0008108

(51) Int. Cl. G11C 16/26; G11C 16/04; G11C 16/08

(52) U.S. Cl. CPC G11C 16/26; G11C 16/0433; G11C 16/08

(57) ABSTRACT

Provided is a storage device including non-volatile memory and a storage controller, where the non-volatile memory includes a plurality of cell strings storing a plurality of source vertex values and a plurality of destination vertex values, and the storage controller reads at least a first destination vertex value corresponding to a first source vertex value from the non-volatile memory, and performs a graphic processing operation based on the read first destination vertex value. A first cell string includes a plurality of first memory cells storing a first source vertex value and connected to word lines of a first group of wordlines, respectively, and at least one second memory cell storing the first destination vertex value and connected to at least one word line of a second group of wordlines.

### CROSS-REFERENCE TO RELATED APPLICATION

This application is based on and claims priority under 35 U.S.C. § 119 to Korean Patent Application No. 10-2023-0008108, filed on Jan. 19, 2023, in the Korean Intellectual Property Office, the disclosure of which is incorporated by reference herein in its entirety.

### BACKGROUND

The inventive concept relates a memory device, and more particularly, to a storage device performing a graphic processing operation, a method of operating the storage device, a non-volatile memory device performing a vertex search operation, and a method of operating the non-volatile memory device.

When the graphic processing operation is performed by a host, the load on the host increases as graph data of the graphic processing operation increases. Methods for a storage device to perform graphics processing operations are being studied to reduce the load on the host.

### SUMMARY

Aspects of the inventive concept provide a storage device capable of improving the operation speed and efficiency of graphic processing operations and an operating method of the storage device.

Aspects of the inventive concept also provide a non-volatile memory device capable of performing search operations on source vertex values and destination vertex values and an operating method of the non-volatile memory device.

According to an aspect of the inventive concept, a storage device includes non-volatile memory including a plurality of cell strings storing a plurality of source vertex values and a plurality of destination vertex values, and a storage controller for reading at least a first destination vertex value corresponding to a first source vertex value among the plurality of source vertex values from the non-volatile memory, and for performing a graphic processing operation based on the read first destination vertex value, wherein a first cell string among the plurality of cell strings includes a plurality of first memory cells storing the first source vertex value and connected to word lines of a first group of wordlines, respectively, and at least one second memory cell storing the first destination vertex value and connected to at least one word line of a second group of wordlines.

According to another aspect of the inventive concept, a storage device includes non-volatile memory including a plurality of cell strings storing a plurality of source vertex values and a plurality of destination vertex values, and a storage controller for reading at least a first source vertex value corresponding to a first destination vertex value among the plurality of destination vertex values from the non-volatile memory, and for performing a graphic processing operation based on the read first source vertex value, wherein a first cell string among the plurality of cell strings includes a plurality of first memory cells storing the first destination vertex value and connected to word lines of a first group of wordlines, respectively, and at least one second memory cell storing a first source vertex value among the at least one source vertex value and connected to at least one word line of a second group of wordlines.

According to another aspect of the inventive concept, a non-volatile memory device includes control logic for generating data by encoding a first source vertex value received from a controller, a row decoder for applying word line voltages according to the first source vertex value to word lines of a first group, respectively, and a memory cell array including a plurality of cell strings storing a plurality of source vertex values and a plurality of destination vertex values, wherein a first cell string among the plurality of cell strings includes a plurality of first memory cells storing the first source vertex value and connected to the word lines of the first group, respectively, and at least one second memory cell storing a first destination vertex value among at least one destination vertex value, and when current flows through the first cell string due to the word line voltages, the non-volatile memory device reads the first destination vertex value through a read operation on the at least one second memory cell.

According to another aspect of the inventive concept, a method of operating a storage device includes a storage controller and non-volatile memory includes transmitting, by the storage controller, a source vertex value to the non-volatile memory, performing, by the non-volatile memory, a read operation for searching for a destination vertex value corresponding to the source vertex value, transmitting, by the non-volatile memory, the destination vertex value to the storage controller, and performing, by the storage controller, a graphic processing operation based on the destination vertex value, wherein the performing of the read operation includes searching for at least one cell string storing the source vertex value by applying word line voltages according to the source vertex value to word lines of a first group, and reading the destination vertex value stored in the at least one cell string by performing a normal read operation on the found at least one cell string.

According to another aspect of the inventive concept, a method of operating non-volatile memory includes receiving a source vertex value from a storage controller, searching for at least one cell string storing the source vertex value, by applying word line voltages according to the source vertex value to word lines of a first group, reading a destination vertex value stored in the at least one cell string by performing a normal read operation on the found at least one cell string, and transmitting the destination vertex value to the storage controller, wherein the at least one cell string includes a plurality of first memory cells storing the source vertex value and connected to the word lines of the first group, respectively, and at least one second memory cell storing the destination vertex value.

### BRIEF DESCRIPTION OF THE DRAWINGS

Embodiments will be more clearly understood from the following detailed description taken in conjunction with the accompanying drawings in which:

FIG. 1A is a block diagram of a storage system according to an embodiment;

FIG. 1B is a block diagram of a storage system according to an embodiment;

FIG. 2 is a graph according to an embodiment;

FIG. 3 is a block diagram of non-volatile memory according to an embodiment;

FIG. 4 is a circuit diagram of a memory block according to an embodiment;

FIG. 5 is a table illustrating vertex values and data corresponding to the vertex values according to an embodiment;

FIG. 6A is a graph illustrating threshold voltage distribution of memory cells according to an embodiment, FIG. 6B is a diagram illustrating a data search method according to an embodiment, and FIG. 6C is a table illustrating current flow according to data stored in a memory cell according to an embodiment;

FIG. 7 is a circuit diagram of non-volatile memory according to an embodiment;

FIG. 8 is a diagram illustrating data programmed into memory cells included in the non-volatile memory of FIG. 7, according to an embodiment;

FIG. 9 is a diagram illustrating a read operation of non-volatile memory when a source vertex value is 0, according to an embodiment;

FIG. 10 is a diagram illustrating a read operation of non-volatile memory when a source vertex value is 2, according to an embodiment;

FIG. 11 is a diagram illustrating a read operation of non-volatile memory when a source vertex value is 1, according to an embodiment;

FIG. 12 is a diagram illustrating a read operation of non-volatile memory when a source vertex value is 3, according to an embodiment;

FIG. 13 is a diagram illustrating a read operation of non-volatile memory when a destination vertex value is 0, according to an embodiment;

FIG. 14 is a diagram illustrating a memory cell array for storing source vertex values and destination vertex values and a page buffer circuit, according to an embodiment;

FIG. 15 is a diagram illustrating a memory cell array for storing source vertex values and destination vertex values and a page buffer circuit, according to an embodiment;

FIG. 16 is a block diagram of a storage device according to an embodiment;

FIG. 17 is a diagram illustrating a memory cell array and a page buffer circuit according to an embodiment;

FIG. 18 is a diagram illustrating a memory cell array and a page buffer circuit according to an embodiment;

FIG. 19 is an updated graph according to an embodiment;

FIG. 20 is a diagram illustrating a page buffer circuit and memory blocks storing source vertex values and destination vertex values according to the updated graph of FIG. 19, according to an embodiment;

FIG. 21 is a block diagram of a storage device according to an embodiment;

FIG. 22 illustrates a memory cell array, a page buffer circuit, and a buffer, according to an embodiment;

FIG. 23 illustrates a method of operating a host, a storage controller, and non-volatile memory, according to an embodiment;

FIG. 24 illustrates a method of operating a storage controller and non-volatile memory according to an embodiment;

FIG. 25 illustrates a method of operating a non-volatile memory device according to an embodiment;

FIG. 26 illustrates a method of operating a non-volatile memory device according to an embodiment; and

FIG. 27 is a diagram of a system to which a storage device is applied, according to an embodiment.

### DETAILED DESCRIPTION OF THE EMBODIMENTS

Hereinafter, embodiments will be described in detail with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

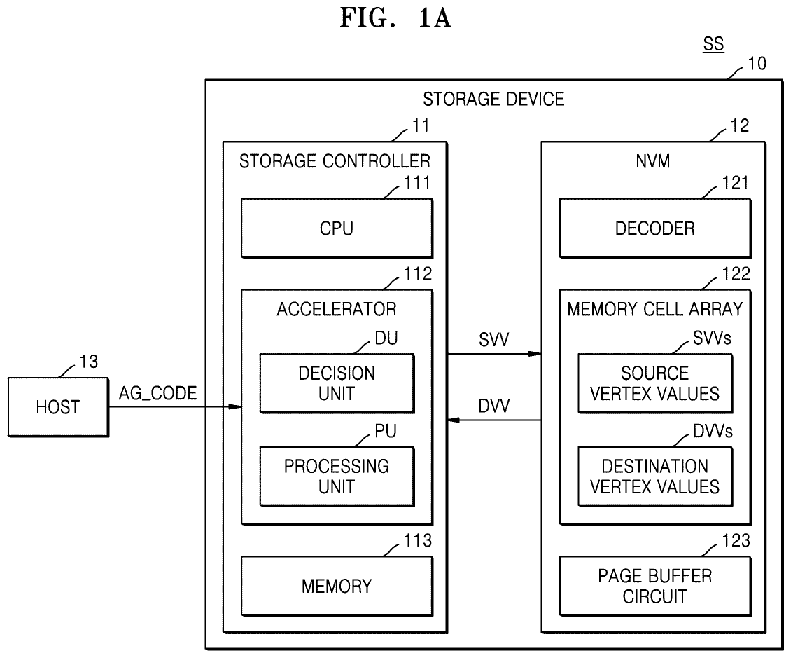

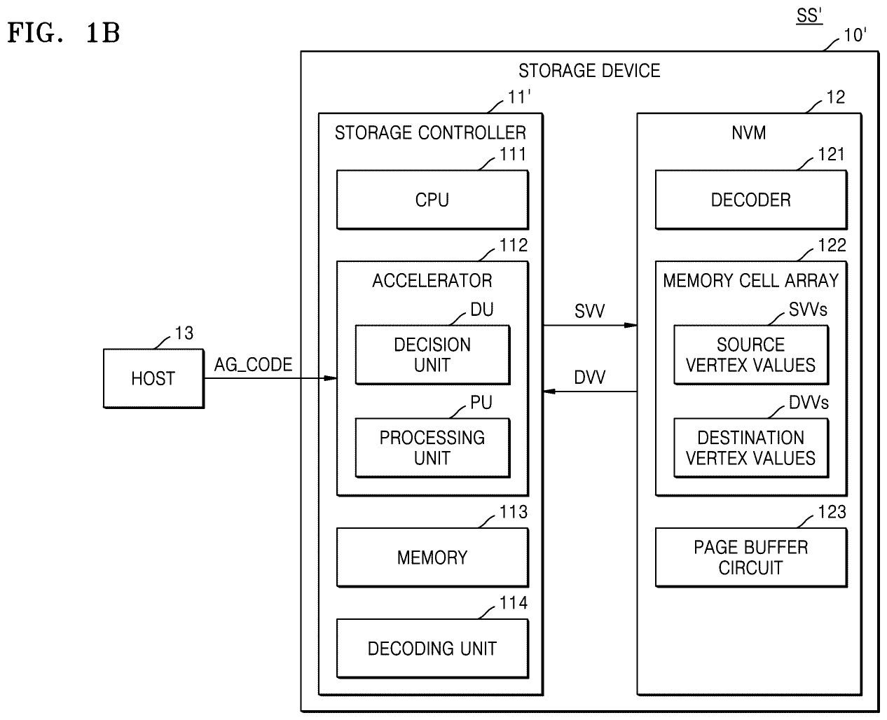

FIG. 1A is a block diagram of a storage system SS according to an embodiment.

Referring to FIG. 1A, the storage system SS may include a storage device 10 including a storage controller 11 and non-volatile memory (NVM) 12. According to an embodiment, the storage controller 11 may be referred to as a controller, a memory controller, or a NVM controller. In addition, the storage system SS may further include a host 13 in communication with the storage device 10. Accordingly, the storage system SS may be referred to as a host-storage system.

The storage controller 11 may include a central processing unit (CPU) 111, an accelerator 112, and memory 113. The CPU 111 may control the overall operation of the storage controller 11. For example, the CPU 111 may be implemented as a controller chip. In an embodiment, the CPU 111 may be implemented as a multi-core processor, e.g., a dual core processor or a quad core processor.

The accelerator 112 may be implemented as a reconfigurable logic chip, such as a field-programmable gate array (FPGA). The memory 113 may be used as buffer memory or operating memory, and may be implemented as, e.g., dynamic random-access memory (DRAM) chip or static random-access memory (SRAM). In an embodiment, the CPU 111, the accelerator 112, and the memory 113 may be implemented as a plurality of respective chips. However, the inventive concept is not limited thereto, and at least two of the CPU 111, the accelerator 112, and the memory 113 may be implemented as the same chip.

The accelerator 112 may receive an algorithm code AG_CODE from the host 13, and may perform an operation according to the received algorithm code AG_CODE. In an embodiment, the operation according to the algorithm code AG_CODE may correspond to a graphic processing operation or a graph processing operation, wherein the algorithm code AG_CODE may correspond to one of a plurality of algorithm codes. For example, the plurality of algorithm codes may include search algorithm codes such as breadth-first search, depth-first search, and best-first search, but the inventive concept is not limited thereto.

In an embodiment, the algorithm code AG_CODE may be received from the host 13 when power is applied to the storage device 10. In an embodiment, the algorithm code AG_CODE may be received from the host 13 during operation of the storage device 10. In an embodiment, the algorithm code AG_CODE received by the accelerator 112 may be changed in real time. In an embodiment, the accelerator 112 may receive the plurality of algorithm codes, and may perform operations corresponding to the plurality of algorithm codes, respectively.

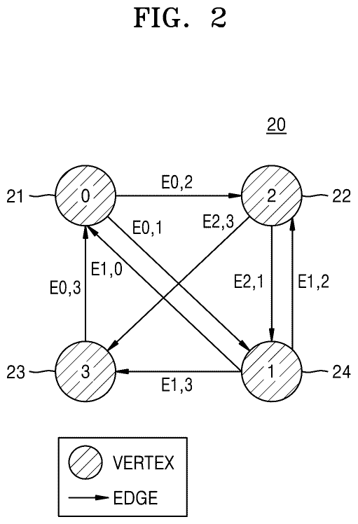

FIG. 2 is a graph 20 according to an embodiment.

Referring to FIG. 2, the graph 20 is a mathematical structure composed of a plurality of vertices and edges connecting the vertices. According to an embodiment, the vertex may be referred to as a node, a peak, an apex, or a point, and the edge may be referred to as a link. wherein the edge may have directionality and may connect a source vertex to a destination vertex. One source vertex may be connected to a plurality of edges, and thus to a plurality of destination vertices.

In an embodiment, the graph 20 may include first to fourth vertices 21 to 24. For example, an edge E0,2 connects and directs the first vertex 21 to the second vertex 22, wherein the first vertex 21 is a source vertex with a vertex value of 0, and the second vertex 22 is a destination vertex with a vertex value of 2. An edge E0,1 connects and directs the first vertex 21 to the fourth vertex 24, wherein the first vertex 21 is a source vertex with a vertex value of 0, and the fourth vertex 24 is a destination vertex with a vertex value of 1. As such, one source vertex may be matched to a plurality of destination vertices.

An edge E2,3 connects and directs the second vertex 22 to the third vertex 23, wherein the second vertex 22 is a source vertex with a vertex value of 2, and the third vertex 23 is a destination vertex with a vertex value of 3. An edge E2,1 connects and directs the second vertex 22 to the fourth vertex 24, wherein the second vertex 22 is a source vertex with a vertex value of 2, and the fourth vertex 24 is a destination vertex with a vertex value of 1. As such, the second vertex 22 may correspond to the destination vertex at edge E0,2, and may correspond to the source vertex at the edges E2,3 and E2,1.

Referring to FIGS. 1A and 2, the accelerator 112 included in the storage controller 11 may perform a graphic processing operation based on a source vertex value SVV and a destination vertex value DVV, and the nonvolatile memory 12 may perform a vertex search operation or a search operation on searching the destination vertex value DVV that matches the source vertex value SVV. Specifically, the NVM 12 may receive the source vertex value SVV from the storage controller 11, read the destination vertex value DVV by performing a search operation based on the received source vertex value SVV, and provide the read destination vertex value DVV to the storage controller 11.

In an embodiment, the NVM 12 may include a decoder 121, a memory cell array 122, and a page buffer circuit 123. The decoder 121 may generate data according to the source vertex value SVV by encoding the source vertex value SVV, and may provide word line voltages corresponding to the generated data to the memory cell array 122. The memory cell array 122 may store source vertex values SVVs and destination vertex values DVVs. The page buffer circuit 123 may buffer at least one destination vertex value DVV read from the memory cell array 122. In an embodiment, the memory cell array 122 may store data encoded with the source vertex values SVVs and data encoded with the destination vertex values DVVs, and the NVM 12 may provide a source vertex value SVV and/or a destination vertex value DVV by decoding the encoded data.

In an embodiment, the NVM 12 may store the data encoded with the source vertex value in a plurality of single-level cells. In an embodiment, the NVM 12 may redundantly store data encoded with the source vertex value in a plurality of cell strings corresponding to a plurality of bit lines, respectively. In an embodiment, the NVM 12 may store the source vertex value in at least one multi-level cell. For example, the multi-level cell may store two or more bits of data per cell.

In an embodiment, the NVM 12 may store data encoded with the destination vertex value in a plurality of single-level cells. In an embodiment, the NVM 12 may redundantly store data encoded with the destination vertex value in a plurality of cell strings corresponding to a plurality of bit lines, respectively. In an embodiment, the NVM 12 may store the destination vertex value in at least one multi-level cell. For example, the multi-level cell may store two or more bits of data per cell.

The accelerator 112 may include a decision unit DU and a processing unit PU. The decision unit DU may decide one of various source vertex values according to the type of graphic processing operation according to the algorithm code AG_CODE. The processing unit PU may perform a graphic processing operation according to the algorithm code AG_CODE. Graphic processing may be used, for example, to model and search websites, among other uses. For example, the graphic processing operation may correspond to PageRank which is an algorithm to rank web pages in search engine results. Specifically, the decision unit DU may decide the source vertex value SVV to be provided to the NVM 12, and may transmit the source vertex value SVV stored in the memory 113 to the NVM 12. The destination vertex value DVV read from the NVM 12 may be stored in the memory 113, and the processing unit PU may perform a graphic processing operation on the destination vertex value DVV stored in the memory 113. As such, it is possible to perform a graphic processing operation within the storage device 10, which may be referred to as an in-storage operation or an in-storage graphic processing operation.

In an embodiment, the algorithm code AG_CODE may correspond to a best-first search operation to search for an optimal path from a starting node to a target node. For example, the processing unit PU may calculate the cost of starting at a starting node and reaching a target node via node n by performing an operation of F(n)=G(n)+H(n), wherein G(n) is the path cost from the starting node to the node n, i.e., the deterministic cost to the current path, and H(n) is the path cost from the node n to the target node, i.e., the deterministic cost from the current to the target node. The decision unit DU may select a vertex whose cost, i.e. F(n), has a minimum value.

When performing graphic processing operations corresponding to a plurality of algorithm codes, respectively, in the host 13, the graphic processing speed may be degraded because a large amount of graph data is required to be transmitted from the storage device 10, and the efficiency of the storage system SS may be degraded because the load on the host 13 is concentrated. However, according to the present embodiment, the storage device 10 may include the accelerator 112 loaded with a graphic processing algorithm and the NVM 12 storing a plurality of source vertex values SVVs and plurality of destination vertex values DVVs. The NVM 12 may perform a search operation on the source vertex value SVV and the destination vertex value DVV, and the accelerator 112 may perform a graphic processing operation on the destination vertex value DVV read from the NVM 12. As such, by performing the graphic processing operation in the storage device 10, the speed of the graphic processing operation may be improved. In addition, the accelerator 112 may reduce the load on the host 13 by performing the graphic processing operation, thereby improving the efficiency of the storage system SS.

In this specification, an embodiment in which the accelerator 112 performs graphic processing operations will be mainly described. However, the inventive concept is not limited thereto, and according to an embodiment, the accelerator 112 may further perform multimedia transcoding or erasure coding, etc. In addition, the accelerator 112 may further perform a machine learning algorithm, such as convolutional neural network (CNN), recurrent neural network (RNN), etc. For example, the accelerator 112 may be configured to perform video transcoding, and may be reconfigured to perform a CNN according to a host command instructing the CNN during operation of the storage system SS.

For example, the accelerator 112 may perform inline processing, pre-processing, post-filtering, cryptography, compression, protocol bridging, etc. For example, the accelerator 112 may perform one or more of sorting, searching, logic, or four arithmetic operations. The logic operation may represent an operation performed by various logic gates such as an AND gate, an OR gate, an XOR gate, a NOR gate, and a NAND gate, or an operation combining two or more thereof. The operation performed by the accelerator 112 is not limited to those described above, and may be any operation corresponding to some of the operations performed by the host 13.

The storage device 10 may include storage media for storing data upon request from the host 13. As an example, the storage device 10 may include at least one of a solid state drive (SSD), embedded memory, and removable external memory. When the storage device 10 is an SSD, the storage device 10 may be a device that conforms to the non-volatile memory express (NVMe) standard. When the storage device 10 is an embedded memory or external memory, the storage device 10 may be a device that conforms to the universal flash storage (UFS) or embedded multi-media card (eMMC) standard. The host 13 and the storage device 10 may each generate and transmit a packet according to an adopted standard protocol.

FIG. 1B is a block diagram of a storage system SS' according to an embodiment.

Referring to FIG. 1B, the storage system SS' may include a storage device 10 including a storage controller 11′ and NVM 12. The storage controller 11′ according to the present embodiment corresponds to a variation of the storage controller 11 of FIG. 1A, and the details described above with reference to FIG. 1A may also be applied to the present embodiment. The storage controller 11′ may further include a decoding unit 114. In an embodiment, the NVM 12 may transmit the encoded destination vertex value DVV, and the decoding unit 114 may generate the original destination vertex value, i.e., the decoded destination vertex value, by decoding the encoded destination vertex value DVV. In an embodiment, the NVM 12 may transmit the encoded source vertex value SVV and the decoding unit 114 may decode the encoded source vertex value SVV, thereby generating the original source vertex value, i.e., the decoded source vertex value, which may also be applied to the following embodiments.

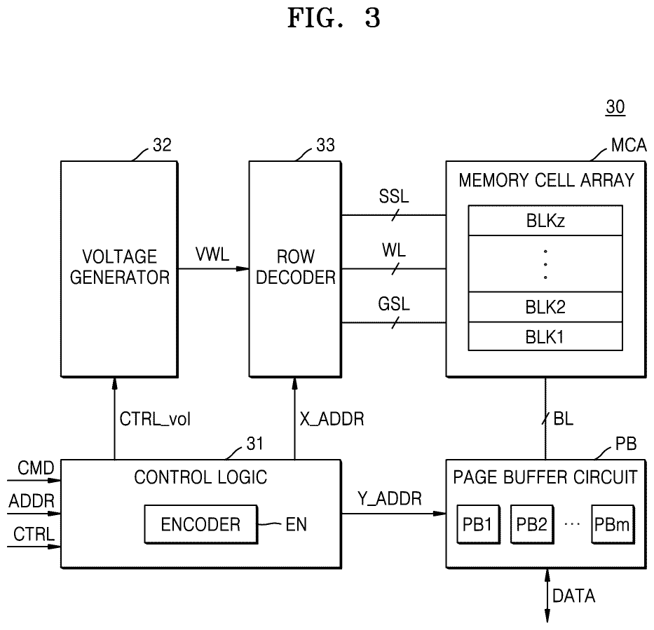

FIG. 3 is a block diagram of NVM 30 according to an embodiment.

Referring to FIG. 3, the NVM 30 may include a memory cell array MCA, a page buffer circuit PB, control logic 31, a voltage generator 32, and a row decoder 33. The NVM 30 may correspond to an implementation example of the NVM 12 of FIG. 1A or 1B. For example, the control logic 31, the voltage generator 32, and the row decoder 33 may correspond to the decoder 121 of FIG. 1A or the decoder 121 of FIG. 1B. For example, the memory cell array MCA and the page buffer circuit PB may correspond to the memory cell array 122 and the page buffer circuit 123 of FIG. 1A or 1B, respectively.

The memory cell array MCA may include a plurality of memory blocks BLK1 to BLKz, each of which may include a plurality of cell strings, and the plurality of cell strings may include a plurality of memory cells connected in series. The memory cell array MCA may be connected to the page buffer circuit PB via bit lines BL, and may be connected to the row decoder 33 via word lines WL, string select lines SSL, and ground select lines GSL.

In an embodiment, the memory cell array MCA may include a three-dimensional memory cell array, and the three-dimensional memory cell array may include a plurality of cell strings. Each of the cell strings may include memory cells respectively connected to the word lines vertically stacked on a substrate. U.S. Pat. Nos. 7,679,133, 8,553,466, 8,654,587, 8,559,235, and U.S. Patent Application Publication No. 2011/0233648 demonstrate examples of three-dimensional memory cell arrays, and are incorporated herein by reference.

In an embodiment, the memory cell array MCA may include flash memory, and the flash memory may include a two-dimensional (2D) NAND memory array or a three-dimensional (3D) vertical NAND (VNAND) memory array. In an embodiment, the memory cell array MCA may include magnetic RAM (MRAM), spin-transfer torque MRAM, conductive bridging RAM (CBRAM), ferroelectric RAM (FeRAM), phase RAM (PRAM), resistive RAM, and other various types of memory.

In the present embodiment, some memory blocks among the plurality of memory blocks BLK1 to BLKz may store source vertex values, destination vertex values, edge values, and/or invalid information, wherein the invalid information may be information for invalidating a connection relationship between the source vertex and the destination vertex. For example, the invalid information may indicate that the connection relationship is invalid by setting the source vertex to a particular value. For example, the invalid information may indicate that the connection relationship is invalid by applying a particular voltage to a word line connected to memory cells of a memory block.

Other memory blocks (besides the memory blocks that store vertex values) among the plurality of memory blocks BLK1 to BLKz may store user data. In some embodiments, rather than some memory blocks storing vertex values, destination vertex values, edge values, and/or invalid information and other memory blocks storing user data, the NVM 30 may include a plurality of memory chips, a plurality of memory dies, and/or a plurality of memory planes, and at least one memory chip among the plurality of memory chips, at least one memory die among the plurality of memory dies, and at least one memory plane among the plurality of memory planes may store source vertex values, destination vertex values, edge values, and/or invalid information, while other memory chips, memory dies, or memory planes may store user data.

The control logic 31 may overall control various operations within the NVM 30. The control logic 31 may output various control signals in response to a command CMD and/or an address ADDR. For example, the control logic 31 may output a voltage control signal CTRL_vol, a row address X_ADDR, and a column address Y_ADDR. In an embodiment, the control logic 31 may include an encoder EN. The encoder EN may generate data by encoding the source vertex value SVV received from the storage controller 11. Although not shown, the control logic 31 may further include a decoder corresponding to the encoder EN. The decoder may decode data received from the page buffer circuit PB to generate the source vertex value and/or the destination vertex value.

The voltage generator 32 may generate various kinds of voltages to perform program, read, and erase operations based on the voltage control signal CTRL_vol. For example, the voltage generator 32 may generate a program voltage, a read voltage, a program verification voltage, an erase voltage, etc., as a word line voltage VWL. In response to the row address X_ADDR, the row decoder 33 may select at least one of the plurality of word lines WL, and may select one of the plurality of string select lines SSL. For example, during a program operation, a search operation, or a read operation, the row decoder 33 may apply word line voltages to the selected word lines. The page buffer circuit PB may select at least one of the bit lines BL in response to the column address Y_ADDR. The page buffer circuit PB may operate as a write driver or a sense amplifier according to an operation mode. The page buffer circuit PB may include a plurality of page buffers PB1 to PBm respectively connected to the bit lines BL, where m is a positive integer.

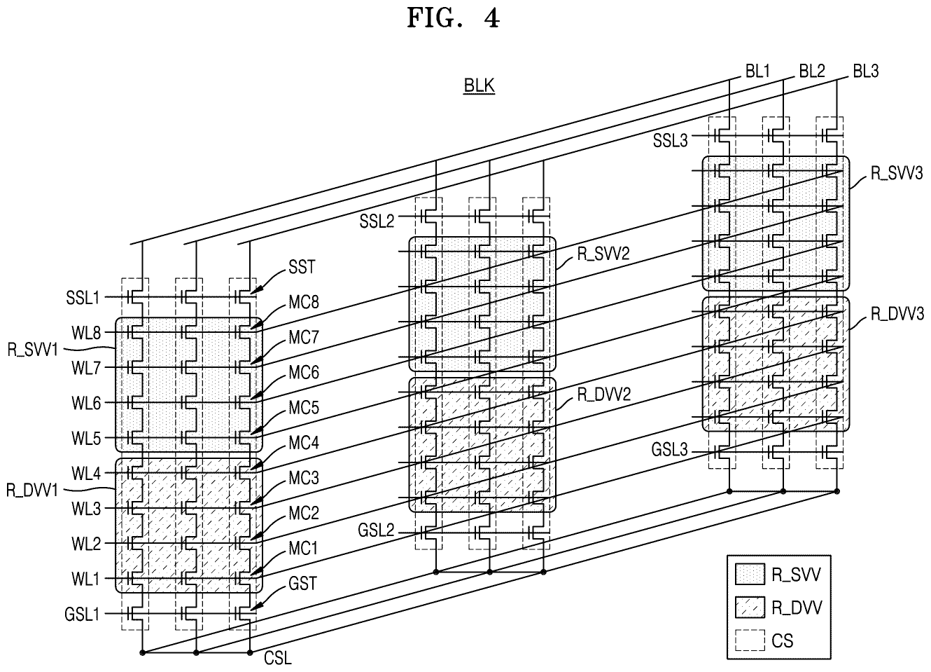

FIG. 4 is a circuit diagram of a memory block BLK according to an embodiment.

Referring to FIG. 4, the memory block BLK may correspond to one of the plurality of memory blocks BLK1 to BLKz of FIG. 3. The memory block BLK may include a plurality of cell strings CS, each of which may include a string select transistor SST, a plurality of memory cells MC1 to MC8, and a ground select transistor GST connected in series. The string select transistor SST, the ground select transistor GST, and the memory cells MC1 to MC8 included in each of the cell strings CS may form a stacked structure along a vertical direction on the substrate.

The string select transistor SST may be connected to corresponding string select lines SSL1 to SSL3. The memory cells MC1 to MC8 may be connected to corresponding word lines WL1 to WL8, respectively. The ground select transistor GST may be connected to corresponding ground select lines GSL1 to GSL3. The string select transistor SST may be connected to a corresponding bit line, and the ground select transistor GST may be connected to a common source line CSL. The number of cell strings CS, the number of word lines, the number of bit lines, the number of ground select lines, and the number of string select lines may be variously changed according to an embodiment.

In an embodiment, the memory block BLK may include a plurality of source vertex value storage regions R_SVV1 to R_SVV3, and a plurality of destination vertex value storage regions R_DVV1 to R_DVV3. For example, the source vertex value storage region R_SVV1 may include memory cells corresponding to the first string select line SSL1 and connected to the word lines WL5 to WL8, and the destination vertex value storage region R_DVV1 may include memory cells corresponding to the first string select line SSL1 and connected to the words lines WL1 to WL4.

For example, the source vertex value storage region R_SVV2 may include memory cells corresponding to the second string select line SSL2 and connected to the word lines WL5 to WL8, and the destination vertex value storage region R_DVV2 may include memory cells corresponding to the second string select line SSL2 and connected to the word lines WL1 to WL4. For example, the source vertex value storage region R_SVV3 may include memory cells corresponding to the third string select line SSL3 and connected to the word lines WL5 to WL8, and the destination vertex value storage region R_DVV3 may include memory cells corresponding to the third string select line SSL3 and connected to the word lines WL1 to WL4.

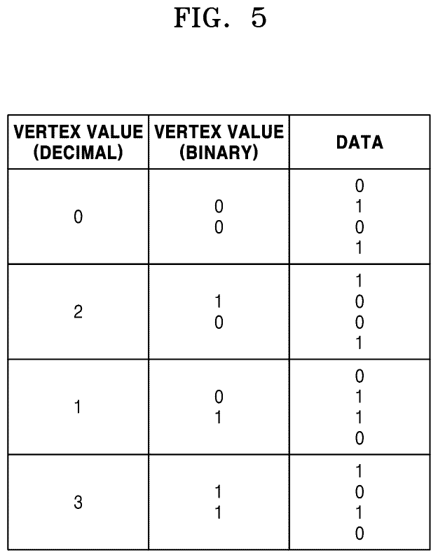

FIG. 5 is a table illustrating vertex values and data corresponding to the vertex values according to an embodiment.

Referring to FIGS. 1A-3 and 5, the control logic 31 may generate data by encoding vertex values. In an embodiment, the NVM 30 may receive a source vertex value from the storage controller 11, and the control logic 31 may generate data by converting the source vertex value into a first value and encoding the converted source vertex value or first value. The encoder EN may generate data by encoding 0 included in the source vertex value as 01 and encoding 1 included in the source vertex value as 10. For example, the source vertex 0 may be converted to the source vertex value 00, and the encoder EN may generate data 0101 by encoding the source vertex value 00 (e.g., by converting each 0 of the number to ‘01’). For example, the source vertex 2 may be converted to the source vertex value 10, and the encoder EN may generate data 1001 by encoding the source vertex value 10 (e.g., by converting the 1 to ‘10’ and converting the 0 to ‘01’). For example, the source vertex 1 may be converted to the source vertex value 01, and the encoder EN may generate data 0110 by encoding the source vertex value 01. For example, the source vertex 3 may be converted to the source vertex value 11, and the encoder EN may generate data 1010 by encoding the source vertex value 11.

However, the inventive concept is not limited thereto, and the NVM 30 may receive a source vertex value from the storage controller 11, and the control logic 31 may generate data by encoding the source vertex value. The encoder EN may generate data by encoding 0 included in the source vertex value as 01 and encoding 1 included in the source vertex value as 10.

In an embodiment, the NVM 30 may receive a destination vertex value from the storage controller 11, and the control logic 31 may generate data by converting the destination vertex value to a first value and encoding the converted destination vertex value or first value. The encoder EN may generate data by encoding 0 included in the destination vertex value as 01 and encoding 1 included in the destination vertex value as 10. However, the inventive concept is not limited thereto, and the NVM 30 may receive a destination vertex value from the storage controller 11, and the control logic 31 may generate data by encoding the destination vertex value. The encoder EN may generate data by encoding 0 included in the destination vertex value as 01 and encoding 1 included in the destination vertex value as 10.

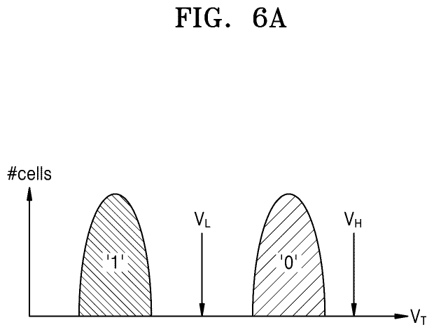

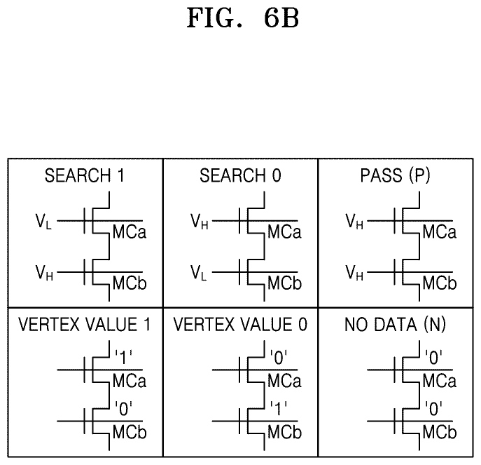

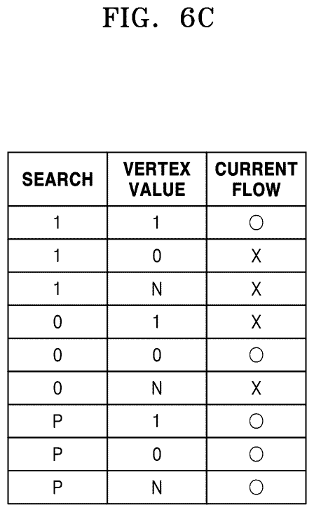

FIG. 6A is a graph illustrating threshold voltage distribution of memory cells according to an embodiment.

Referring to FIG. 6A, the threshold voltage distribution of memory cells may be expressed as the number of memory cells that have a particular threshold voltage VT. Each of the memory cells may be a single-level cell storing data 1 or 0. The memory cells storing data 1 may have threshold voltages corresponding to a first threshold voltage range, and the memory cells storing data 0 may have threshold voltages corresponding to a second threshold voltage range. The upper limit voltage level of the first threshold voltage range may be lower than the voltage level of a first voltage V_{L}. The lower limit voltage level of the second threshold voltage range may be higher than the voltage level of the first voltage V_{L}, and the upper limit voltage level of the second threshold voltage range may be lower than a second voltage VH. VH may be higher than V_{L}.

FIG. 6B is a diagram illustrating a data search method according to an embodiment.

Referring to FIG. 6B, serially connected memory cells MCa and MCb may be used to store data corresponding to a vertex value. For example, data 10 corresponding to the vertex value 1 may be stored in the memory cells MCa and MCb by storing data 1 in the memory cell MCa and storing data 0 in the memory cell MCb. For example, data 01 corresponding to the vertex value 0 may be stored in the memory cells MCa and MCb by storing data 0 in the memory cell MCa and storing data 1 in the memory cell MCb. For example, data 00 indicating no data may be stored in the memory cells MCa and MCb by storing data 0 in the memory cell MCa and storing data 0 in the memory cell MCb.

FIG. 6C is a table illustrating current flow according to data stored in a memory cell according to an embodiment.

Referring to FIGS. 6B and 6C, for example, to search for the vertex value 1 (e.g., to determine whether two adjacent cells store the encoded ‘1’ value of 10), the first voltage V_{L} may be applied to the word line connected to the memory cell MCa, and the second voltage VH may be applied to the word line connected to the memory cell MCb. When the vertex value stored in the memory cells MCa and MCb is encoded 1 (e.g., 10), current may flow through the memory cells MCa and MCb. On the other hand, when the vertex value stored in the memory cells MCa and MCb is not 1 (e.g., is 01), no current will flow through both. memory cells MCa and MCb because the memory cell MCa will only turn on for a low voltage V_{L} when a ‘1’ is stored. For example, to search for the vertex value 0 (e.g., to determine whether two adjacent cells store the encoded ‘0’ value of 01), the second voltage VH may be applied to the word line connected to the memory cell MCa, and the first voltage V_{L} may be applied to the word line connected to the memory cell MCb. When the vertex value stored in the memory cells MCa and MCb is 0, current may flow through the memory cells MCa and MCb. On the other hand, when the vertex value stored in the memory cells MCa and MCb is not 0 and the second voltage VH is applied to the word line connected to the memory cell MCa, and the first voltage V_{L} is applied to the word line connected to the memory cell MCb, no current will flow through both memory cells MCa and MCb. When the second voltage VH is applied to the word lines connected to the memory cells MCa and MCb, current may flow through the memory cells MCa and MCb regardless of the vertex value stored in the memory cells MCa and MCb.

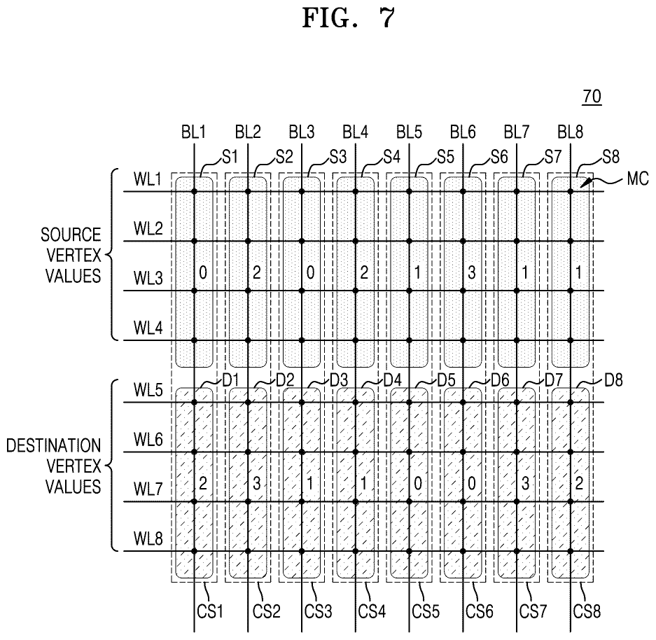

FIG. 7 is a circuit diagram of NVM 70 according to an embodiment.

Referring to FIG. 7, the NVM 70 may store source vertex values and destination vertex values. The NVM 70 may include a plurality of memory cells MC respectively positioned in regions where the plurality of word lines WL1 to WL8 intersect with the plurality of bit lines BL1 to BL8. For example, the source vertex values may be stored in the first memory cells connected to the word lines WL1 to WL4 of the first group, and the destination vertex values may be stored in the second memory cells connected to the words lines WL5 to WL8 of the second group. For example, each of the first and second memory cells may be single-level cells. For example, a memory controller may control the first and second memory cells to be single-level cells, so that they store one bit. The number of word lines of the first group and the number of first memory cells corresponding to the source vertex value may be variously changed according to different embodiments. In addition, the number of word lines of the second group and the number of second memory cells corresponding to the destination vertex value may be variously changed according to different embodiments.

In an embodiment, the NVM 70 may include a plurality of cell strings CS1 to CS8 connected to the plurality of bit lines BL1 to BL8, respectively. For example, the plurality of cell strings CS1 to CS8 may be included in one memory block. However, the inventive concept is not limited thereto, and the plurality of cell strings CS1 to CS8 may be divided into a plurality of groups, which may be included in different memory blocks, respectively.

The first cell string CS1 may include first memory cells storing a first source vertex value S1 and connected to the word lines WL1 to WL4 of the first group, respectively, and second memory cells storing a first destination vertex value D1 and connected to the words lines WL5 to WL8 of the second group, respectively. The second cell string CS2 may include first memory cells storing a second source vertex value S2 and connected to the word lines WL1 to WL4 of the first group, respectively, and second memory cells storing a second destination vertex value D2 and connected to the words lines WL5 to WL8 of the second group, respectively. The third cell string CS3 may include first memory cells storing a third source vertex value S3 and connected to the word lines WL1 to WL4 of the first group, respectively, and second memory cells storing a third destination vertex value D3 and connected to the words lines WL5 to WL8 of the second group, respectively. The fourth cell string CS4 may include first memory cells storing a fourth source vertex value S4 and connected to the word lines WL1 to WL4 of the first group, respectively, and second memory cells storing a fourth destination vertex value D4 and connected to the words lines WL5 to WL8 of the second group, respectively. The above description of the first to fourth cell strings CS1 to CS4 may also be applied to the following embodiments.

The fifth cell string CS5 may include first memory cells storing a fifth source vertex value S5 and connected to the word lines WL1 to WL4 of the first group, respectively, and second memory cells storing a fifth destination vertex value D5 and connected to the words lines WL5 to WL8 of the second group, respectively. The sixth cell string CS6 may include first memory cells storing a sixth source vertex value S6 and connected to the word lines WL1 to WL4 of the first group, respectively, and second memory cells storing a sixth destination vertex value D6 and connected to the words lines WL5 to WL8 of the second group, respectively. The seventh cell string CS7 may include first memory cells storing a seventh source vertex value S7 and connected to the word lines WL1 to WL4 of the first group, respectively, and second memory cells storing a seventh destination vertex value D7 and connected to the words lines WL5 to WL8 of the second group, respectively. The eighth cell string CS8 may include first memory cells storing an eighth source vertex value S8 and connected to the word lines WL1 to WL4 of the first group, respectively, and second memory cells storing an eighth destination vertex value D8 and connected to the words lines WL5 to WL8 of the second group, respectively. The above description of the fifth to eighth cell strings CS5 to CS8 may also be applied to the following embodiments.

Referring to FIGS. 2 and 7, for example, the first and third source vertex values S1 and S3 may be 0, and the first and second destination vertex values D1 and D3 may be 2 and 1, respectively. For example, the second and fourth source vertex values S2 and S4 may be 2, and the second and fourth destination vertex values D2 and D4 may be 3 and 1, respectively. For example, the fifth, seventh, and eighth source vertex values S5, S7, and S8 may be 1, and the fifth, seventh, and eighth destination vertex values D5, D7, and D8 may be 0, 3, and 2, respectively. For example, the sixth source vertex value S6 may be 3, and the sixth destination vertex value D6 may be 0.

In an embodiment, the NVM 70 may include a plurality of memory blocks and may simultaneously apply word line voltages according to the source vertex value to the plurality of the memory blocks. Accordingly, the vertex search operation may be performed on the plurality of memory blocks in parallel, and the time required for the vertex search operation may be reduced.

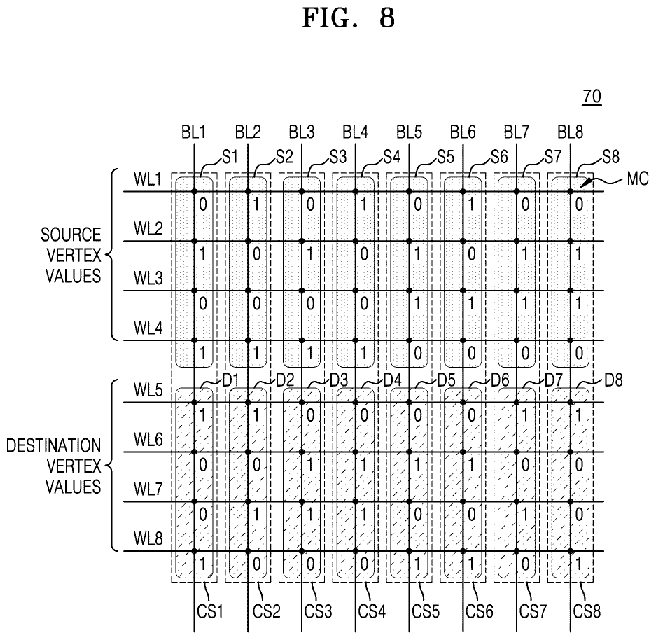

FIG. 8 is a diagram illustrating data programmed into memory cells included in the NVM 70 of FIG. 7, according to an embodiment.

Referring to FIGS. 2, 7 and 8, the first memory cells storing source vertex values may be implemented as first single-level cells, and the second memory cells storing destination vertex values may be implemented as second single-level cells. For example, the first source vertex value S1 may be encoded as data 0101 and stored in the first single-level cells, and the first destination vertex value D1 may be encoded as data 1001 and stored in the second single-level cells. For example, the second source vertex value S2 may be encoded as data 1001 and stored in the first single-level cells, and the second destination vertex value D2 may be encoded as data 1010 and stored in the second single-level cells. For example, the third source vertex value S3 may be encoded as data 0101 and stored in the first single-level cells, and the third destination vertex value D3 may be encoded as data 0110 and stored in the second single-level cells. For example, the fourth source vertex value S4 may be encoded as data 1001 and stored in the first single-level cells, and the fourth destination vertex value D4 may be encoded as data 0110 and stored in the second single-level cells.

For example, the fifth source vertex value S5 may be encoded as data 0110 and stored in the first single-level cells, and the fifth destination vertex value D5 may be encoded as data 0101 and stored in the second single-level cells. For example, the sixth source vertex value S6 may be encoded as data 1010 and stored in the first single-level cells, and the sixth destination vertex value D6 may be encoded as data 0101 and stored in the second single-level cells. For example, the seventh source vertex value S7 may be encoded as data 0110 and stored in the first single-level cells, and the seventh destination vertex value D7 may be encoded as data 1010 and stored in the second single-level cells. For example, the eighth source vertex value S8 may be encoded as data 0110 and stored in the first single-level cells, and the eighth destination vertex value D8 may be encoded as data 1001 and stored in the second single-level cells.

Hereinafter, the destination vertex value search operation of the NVM 70 may be described with reference to FIGS. 1A and 8. In an embodiment, the destination vertex value search operation of the NVM 70 may include two-stage read operations. Specifically, the two-stage read operations may include a first stage of searching for a cell string storing a source vertex value and a second stage of reading a destination vertex value from the found cell string.

In the first stage, to search for a cell string in which the source vertex value SVV received from the storage controller 11 is stored, word line voltages according to the source vertex value SVV may be applied to the word lines WL1 to WL4 of the first group, thereby turning on only the groups of first memory cells storing the source vertex value SVV. In an embodiment, a pass voltage may be applied to the word lines WL5 to WL8 of the second group, so that the second memory cells may all be turned on regardless of the data stored in the second memory cells. Accordingly, current may flow only to a cell string that stores the source vertex value SVV among the plurality of cell strings CS1 to CS8, so that cell strings storing the source vertex value SVV may be searched.

However, the inventive concept is not limited to the above-described embodiment, and according to some embodiments, word line voltages according to the source vertex value SVV may be applied to the word lines WL1 to WL4 of the first group and no pass voltage may be applied to the words lines WL5 to WL8 of the second group. With only the first memory cells storing the source vertex value SVV turned on, the voltage level of the bit lines BL1 to BL8 may be reduced by charge sharing. The cell string corresponding to the bit line having the reduced voltage level equal to or greater than a reference level may be decided as a cell string storing the source vertex value SVV. Alternatively, the cell string corresponding to the bit line having the reduced voltage level which is the highest level may be decided as the cell string storing the source vertex value SVV.

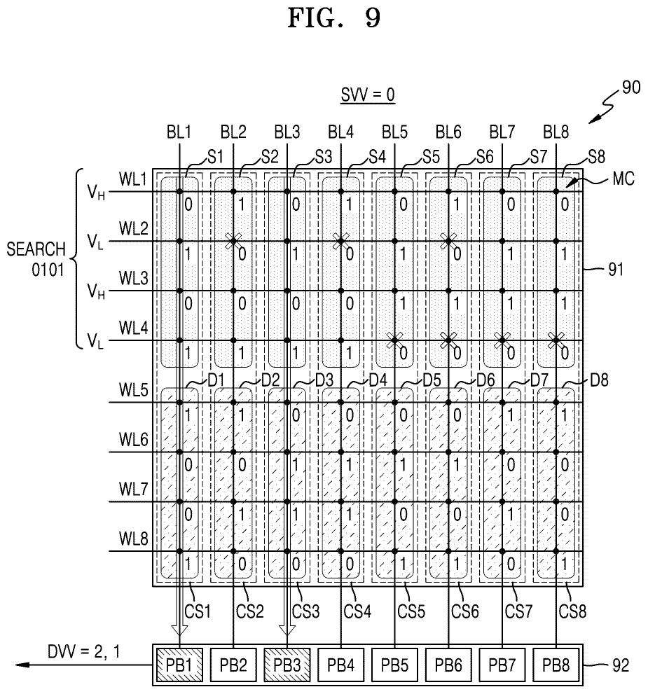

In the second stage, the destination vertex value may be read by performing a normal read operation only on the cell strings storing the source vertex value SVV. In an embodiment, when only the bit line storing the source vertex value SVV is active, the destination vertex value DVV may be read from the second memory cells included in the selected cell string. In an embodiment, when selecting the cell strings connected to the bit lines having the reduced voltage level equal to or greater than the reference level, only the cell strings storing the source vertex value SVV are selected and a voltage may be applied to only the bit lines connected to the selected cell strings. Since cell strings that do not store the source vertex value SVV are not selected, the voltage may not be applied to the bit lines connected to the unselected cell strings, thereby reducing power consumption due to the read operation. A destination vertex value read operation of the NVM is described with reference to FIGS. 9 to 12.

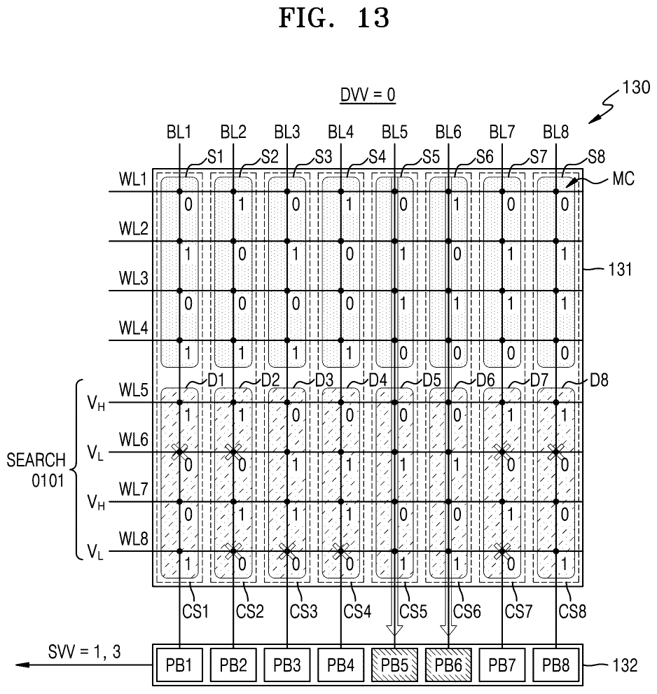

A source vertex search operation of the NVM 70 may also include two-stage read operations. Specifically, the two-stage read operations may include a first stage of searching for a cell string storing the destination vertex value DVV and a second stage of reading the source vertex value SVV from the found cell string. The source vertex value read operation of the NVM may be described in more detail with reference to FIG. 13.

FIG. 9 is a diagram illustrating a read operation of NVM 90 when a source vertex value SVV is 0, according to an embodiment.

Referring to FIGS. 1A, 2 and 9, when the source vertex value SVV received from the storage controller 11 is 0, the NVM 90 may encode data 0101 from 0, which is the source vertex value SVV. Then, to search for the cell string corresponding to 0 which is the source vertex value SVV, the word line voltages corresponding to data 0101, i.e., V_{H}, V_{L}, V_{H}, V_{L}, may be applied to the word lines WL1 to WL4 of the first group, respectively. The memory cells storing data 0 among the first memory cells connected to the word line WL2 may be turned off, and the memory cells storing data 0 among the first memory cells connected to the word line WL4 may be turned off. The first memory cells storing the first and third source vertex values S1 and S3 corresponding to 0 which is the source vertex value SVV may be turned on, whereby current may flow through the first and third cell strings CS1 and CS3, which may be selected as cell strings storing the source vertex value SVV.

The normal read operation may then be performed on the second memory cells included in the selected first and third cell strings CS1 and CS3. The data stored in the second memory cells included in the selected first and third cell strings CS1 and CS3 may be read while changing the read voltages applied to the word lines WL5 to WL8 of the second group. The data read from the second memory cells of the first cell string CS1 may correspond to the first destination vertex value D1, e.g., 2, and may be stored in a first page buffer PB1. The data read from the second memory cells of the third cell string CS3 may correspond to the third destination vertex value D3, e.g., 1, and may be stored in a third page buffer PB3. The first and third destination vertex values D1 and D3 stored in the first and third page buffers PB1 and PB3, respectively, may be transmitted to the storage controller 11.

Hereinafter, the normal read operation on the second memory cells included in the first and third cell strings CS1 and CS3 will be described in detail. In an embodiment, a sequential read operation may be performed on the second memory cells connected to the word lines WL5 to WL8, respectively, by applying a read voltage sequentially to the words lines WL5 to WL8, and may store data sequentially read from the second memory cells included in the first and third cell strings CS1 and CS3 to the first and third page buffers PB1 and PB3, respectively. The data stored in the first and third page buffers PB1 and PB3 respectively may be decoded as destination vertex values, and the decoded destination vertex values may be transmitted to the storage controller 11.

For example, data 1 and 0 may be read from second memory cells connected to the word line WL5, and may be stored in the first and third page buffers PB1 and PB3, respectively, by applying a read voltage to the word line WL5. The data 0 and 1 may then be read from the second memory cells connected to the word line WL6 by applying a read voltage to the word line WL6, and may be stored in the first and third page buffers PB1 and PB3, respectively. The data 0 and 1 may then be read from the second memory cells connected to the word line WL7 by applying a read voltage to the word line WL7, and may be stored in the first and third page buffers PB1 and PB3, respectively. The data 1 and 0 may then be read from the second memory cells connected to the word line WL8 by applying a read voltage to the word line WL8, and may be stored in the first and third page buffers PB1 and PB3, respectively.

As such, data 1001 sequentially read from the second memory cells of the first cell string CS1 may be decoded as the destination vertex value 2, and data 0110 sequentially read from the second memory cells of the third cell string CS3 may be decoded as the destination vertex value 1. For example, the control logic 31 may receive data 1001 from the first page buffer PB1, output the destination vertex value 2 by decoding the data 1001, and transmit the destination vertex value 2 to the storage controller 11. For example, the control logic 31 may receive data 0110 from the third page buffer PB3, output the destination vertex value 1 by decoding the data 0110, and transmit the destination vertex value 1 to the storage controller 11.

However, the inventive concept is not limited to the above-described embodiment, and in some embodiments, a read operation may be performed in page units from the second memory cells included in the first to eighth cell strings CS1 to CS8, and the page buffer circuit 92 may store data of an entire page. Only the data stored in the selected first and third cell strings CS1 and CS3 may be decoded as the destination vertex values, and the decoded destination vertex values may be transmitted to the storage controller 11.

In an embodiment, the NVM 90 may include a plurality of memory blocks and may simultaneously apply word line voltages corresponding to data 0101 to the plurality of the memory blocks, thereby reducing the time spent for a search operation on cell strings storing 0 which is the source vertex value SVV.

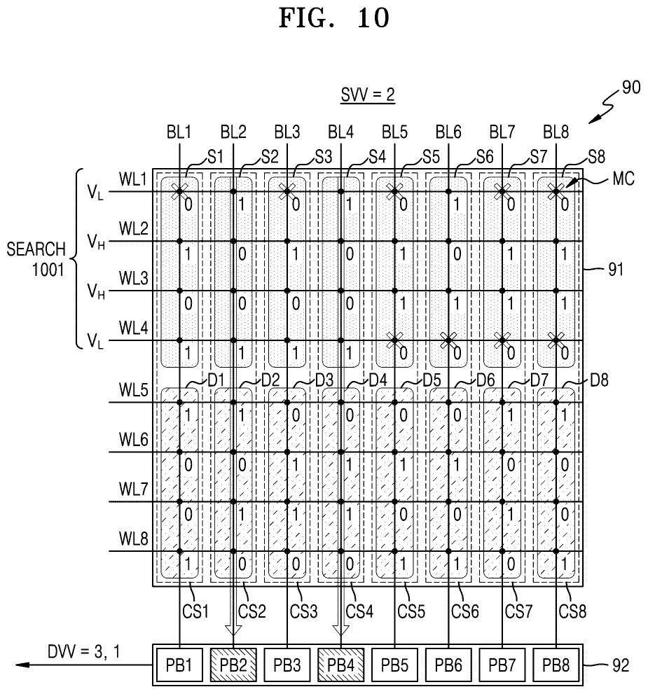

FIG. 10 is a diagram illustrating a read operation of NVM 90 when a source vertex value SVV is 2, according to an embodiment.

Referring to FIGS. 1A, 2 and 10, when the source vertex value SVV received from the storage controller 11 is 2, the NVM 90 may encode data 1001 from 2 which is the source vertex value SVV. Then, to search for the cell string corresponding to 2, which is the source vertex value SVV, word line voltages corresponding to data 1001, i.e., V_{L}, V_{H}, V_{H}, V_{L}, may be applied to the word lines WL1 to WL4 of the first group, respectively. The memory cells storing data 0 among the first memory cells connected to the word line WL1 may be turned off, and the memory cells storing data 0 among the first memory cells connected to the word line WL4 may be turned off. The first memory cells storing the second and fourth source vertex values S2 and S4 corresponding to 2 which is the source vertex value SVV may be turned on, whereby current may flow through the second and fourth cell strings CS2 and CS4, which may be selected as cell strings storing the source vertex value SVV.

The normal read operation may then be performed on the second memory cells included in the selected second and fourth cell strings CS2 and CS4, and may include, for example, reading the second memory cells according to a typical non-volatile memory read operation (e.g., VNAND operation). The data stored in the second memory cells included in the selected second and fourth cell strings CS2 and CS4 may be read while changing the read voltages applied to the word lines WL5 to WL8 of the second group. The data read from the second memory cells of the second cell string CS2 may correspond to the second destination vertex value D2, e.g., 3, and may be stored in the second page buffer PB2. The data read from the second memory cells of the fourth cell string CS4 may correspond to the fourth destination vertex value D4, e.g., 1, and may be stored in the fourth page buffer PB4. The second and fourth destination vertex values D2 and D4 stored in the second and fourth page buffers PB2 and PB4, respectively, may be transmitted to the storage controller 11.

Hereinafter, the normal read operation on the second memory cells included in the second and fourth cell strings CS2 and CS4 may be described in detail. In an embodiment, the sequential read operation may be performed on the second memory cells connected to the word lines WL5 to WL8, respectively, by applying a read voltage sequentially to the word lines WL5 to WL8, and may store data sequentially read from the second memory cells included in the second and fourth cell strings CS2 and CS4 into the second and fourth page buffers PB2 and PB4, respectively. The data stored in the second and fourth page buffers PB2 and PB4, respectively, may be decoded as the destination vertex values, and the decoded destination vertex values may be transmitted to the storage controller 11.

For example, data 1 and 0 may be read from the second memory cells connected to the word line WL5 by applying a read voltage to the word line WL5, and may be stored in the second and fourth page buffers PB2 and PB4, respectively. Data 0 and 1 may then be read from the second memory cells connected to the word line WL6 by applying a read voltage to the word line WL6, and may be stored in the second and fourth page buffers PB2 and PB4, respectively. Data 1 and 1 may then be read from the second memory cells connected to the word line WL7 by applying a read voltage to the word line WL7, and may be stored in the second and fourth page buffers PB2 and PB4, respectively. Data 0 and 0 may then be read from the second memory cells connected to the word line WL8 by applying a read voltage to the word line WL8, and may be stored in the second and fourth page buffers PB2 and PB4, respectively.

As such, data 1010 sequentially read from the second memory cells of the second cell string CS2 may be decoded as the destination vertex value 3, and data 0110 sequentially read from the second memory cells of the fourth cell string CS4 may be decoded as the destination vertex value 1. For example, the control logic 31 may receive data 1010 from the second page buffer PB2, output the destination vertex value 3 by decoding the data 1010, and transmit the destination vertex value 3 to the storage controller 11. For example, the control logic 31 may receive the data 0110 from the fourth page buffer PB4, output the destination vertex value 1 by decoding the data 0110, and transmit the destination vertex value 1 to the storage controller 11.

However, the inventive concept is not limited to the above-described embodiment, and in some embodiments, a read operation may be performed in page units from the second memory cells included in the first to eighth cell strings CS1 to CS8, and the page buffer circuit 92 may store data of an entire page. Only the data stored in the selected second and fourth cell strings CS2 and CS4 may be decoded as the destination vertex value, and the decoded destination vertex value may be transmitted to the storage controller 11.

In an embodiment, the NVM 90 may include a plurality of memory blocks and may simultaneously apply word line voltages corresponding to data 1001 to the plurality of the memory blocks, thereby reducing the time spent for a search operation on cell strings storing 2 which is the source vertex value SVV.

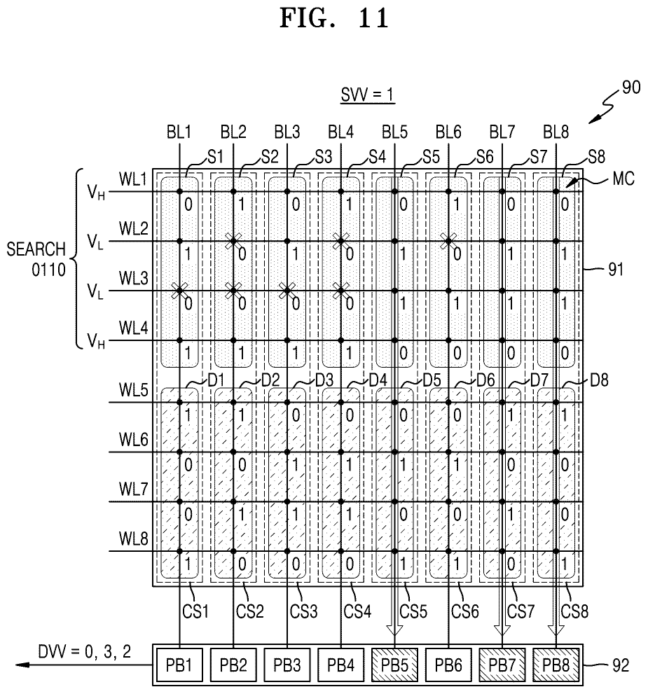

FIG. 11 is a diagram illustrating a read operation of NVM 90 when a source vertex value SVV is 1, according to an embodiment.

Referring to FIGS. 1A, 2 and 11, when the source vertex value SVV received from the storage controller 11 is 1, the NVM 90 may encode data 0110 from 1, which is the source vertex value SVV. Then, to search for the cell string corresponding to 1 which is the source vertex value SVV, the word line voltages corresponding to the data 0110, i.e., V_{H}, V_{L}, V_{L}, V_{H}, may be applied to the word lines WL1 to WL4 of the first group, respectively. The memory cells storing data 0 among the first memory cells connected to the word line WL2 may be turned off, and the memory cells storing data 0 among the first memory cells connected to the word line WL3 may be turned off. The first memory cells storing the fifth, seventh, and eighth source vertex values S5, S7, and S8 corresponding to 1 which is the source vertex value SVV may be turned on, whereby current may flow through the fifth, seventh and eighth cell strings CS5, CS7, and CS8, which may be selected as cell strings storing the source vertex value SVV.

The normal read operation may then be performed on the second memory cells included in the selected fifth, seventh, and eighth cell strings CS5, CS7, and CS8. The data stored in the second memory cells included in the selected fifth, seventh, and eighth cell strings CS5, CS7, and CS8 may be read while changing the read voltages applied to the word lines WL5 to WL8 of the second group. The data read from the second memory cells of the fifth cell string CS5 may correspond to the fifth destination vertex value D5, e.g., 0, and may be stored in the fifth page buffer PB5. The data read from the second memory cells of the seventh cell string CS7 may correspond to the seventh destination vertex value D7, e.g., 3, and may be stored in the seventh page buffer PB7. The data read from the second memory cells of the eighth cell string CS8 may correspond to the eighth destination vertex value D8, e.g., 2, and may be stored in the eighth page buffer PB8. The fifth, seventh and eighth destination vertex values D5, D7, and D8 stored in the fifth, seven and eighth page buffers PB5, PB7, and PB8, respectively, may be transmitted to the storage controller 11.

Hereinafter, the normal read operation on the second memory cells included in the fifth, seventh and eighth cell strings CS5, CS7, and CS8 may be described in detail. In an embodiment, the sequential read operation may be performed on the second memory cells connected to the word lines WL5 to WL8, respectively, by applying a read voltage sequentially to the words lines WL5 to WL8, and may store data sequentially read from the second memory cells included in the fifth, seventh, and eighth cell strings CS5, CS7, and CS8 into the fifth, seventh, and eighth page buffers PB5, PB7, and PB8, respectively. The data stored in the fifth, seventh, and eighth page buffers PB5, PB7, and PB8, respectively, may be decoded as the destination vertex values, and the decoded destination vertex values may be transmitted to the storage controller 11.

For example, data 0, 1, and 1 may be read from the second memory cells connected to the word line WL5 by applying a read voltage to the word line WL5, and may be stored in the fifth, seventh, and eighth page buffers PB5, PB7, and PB8, respectively. Data 1, 0, and 0 may then be read from the second memory cells connected to the word line WL6 by applying a read voltage to the word line WL6, and may be stored in the fifth, seventh, and eighth page buffers PB5, PB7, and PB8, respectively. Data 0, 1, and 0 may then be read from the second memory cells connected to the word line WL7 by applying a read voltage to the word line WL7, and may be stored in the fifth, seventh, and eighth page buffers PB5, PB7, and PB8, respectively. Data 1, 0, and 1 may then be read from the second memory cells connected to the word line WL8 by applying a read voltage to the word line WL8, and may be stored in the fifth, seventh, and eighth page buffers PB5, PB7, and PB8, respectively.

As such, data 0101 sequentially read from the second memory cells of the fifth cell string CS5 may be decoded as the destination vertex value 0, data 1010 sequentially read from the second memory cells of the seventh cell string CS7 may be decoded as the destination vertex value 3, and data 1001 sequentially read from the second memory cells of the eighth cell string CS8 may be decoded as the destination vertex value 2. For example, the control logic 31 may receive data 0101 from the fifth page buffer PB5, output the destination vertex value 0 by decoding the data 0101, and transmit the destination vertex value 0 to the storage controller 11. For example, the control logic 31 may receive data 1010 from the seventh page buffer PB7, output the destination vertex value 3 by decoding the data 1010, and transmit the destination vertex value 3 to the storage controller 11. For example, the control logic 31 may receive data 1001 from the eighth page buffer PB8, output the destination vertex value 2 by decoding the data 1001, and transmit the destination vertex value 2 to the storage controller 11.

However, the inventive concept is not limited to the above-described embodiment, and in some embodiments, a read operation may be performed in page units from the second memory cells included in the first to eighth cell strings CS1 to CS8, and the page buffer circuit 92 may store data of an entire page. Only the data stored in the selected fifth, seventh, and eighth cell strings CS5, CS7, and CS8 may be decoded as the destination vertex value, and the decoded destination vertex value may be transmitted to the storage controller 11.

In an embodiment, the NVM 90 may include a plurality of memory blocks and may simultaneously apply word line voltages corresponding to data 0110 to the plurality of the memory blocks, thereby reducing the time spent for a search operation on cell strings storing 1 which is the source vertex value SVV.

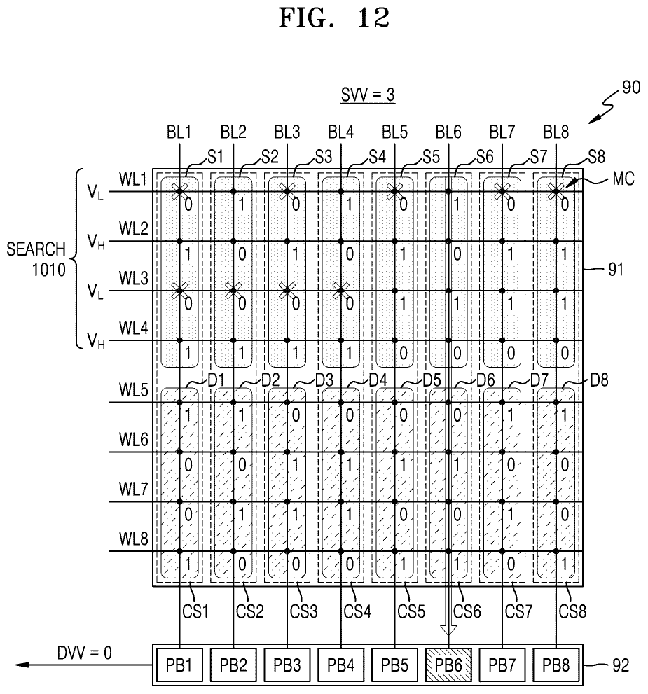

FIG. 12 is a diagram illustrating a read operation of NVM 90 when a source vertex value SVV is 3, according to an embodiment.

Referring to FIGS. 1A, 2 and 12, when the source vertex value SVV received from the storage controller 11 is 3, the NVM 90 may encode data 1010 from 3 which is the source vertex value SVV. Then, to search for the cell string corresponding to 3 which is the source vertex value SVV, word line voltages corresponding to data 1010, i.e., V_{L}, V_{H}, V_{L}, V_{H}, may be applied to the word lines WL1 to WL4 of the first group, respectively. The memory cells storing data 0 among the first memory cells connected to the word lines WL1 and WL3 may be turned off. The first memory cells storing the sixth source vertex value S6 may be turned on, whereby current may flow through the sixth cell string CS6, which may be selected as cell strings storing the source vertex value SVV.

The normal read operation may then be performed on the second memory cells included in the selected sixth cell string CS6. The data stored in the second memory cells included in the selected sixth cell string CS6 may be read while changing the read voltages applied to the word lines WL5 to WL8 of the second group. The data read from the second memory cells of the sixth cell string CS6 may correspond to the sixth destination vertex value D6, e.g., 0, and may be stored in the sixth page buffer PB6. The sixth destination vertex value D6 stored in the sixth page buffer PB6 may be transmitted to the storage controller 11.

Hereinafter, the normal read operation on the second memory cells included in the sixth cell string CS6 may be described in detail. In an embodiment, the sequential read operation may be performed on the second memory cells connected to the word lines WL5 to WL8, respectively, by applying a read voltage sequentially to the words lines WL5 to WL8, and may store data sequentially read from the second memory cells included in the sixth cell string CS6 into the sixth page buffer PB6. The data stored in the sixth page buffer PB6 may be decoded as the destination vertex values, and the decoded destination vertex values may be transmitted to the storage controller 11.

For example, data 0 may be read from the second memory cells connected to the word line WL5 by applying a read voltage to the word line WL5, and may be stored in the sixth page buffer PB6. Data 1 may then be read from the second memory cells connected to the word line WL6 by applying a read voltage to the word line WL6, and may be stored in sixth page buffer PB6. Data 0 may then be read from the second memory cells connected to the word line WL7 by applying a read voltage to the word line WL7, and may be stored in sixth page buffer PB6. Data 1 may then be read from the second memory cells connected to the word line WL8 by applying a read voltage to the word line WL8, and may be stored in sixth page buffer PB6.

As such, data 0101 sequentially read from the second memory cells of the sixth cell string CS6 may be decoded as the destination vertex value 0. For example, the control logic 31 may receive the data 0101 from the sixth page buffer PB6, output the destination vertex value 0 by decoding the data 0101, and transmit the destination vertex value 0 to the storage controller 11.

However, the inventive concept is not limited to the above-described embodiment, and in some embodiments, a read operation may be performed in page units from the second memory cells included in the first to eighth cell strings CS1 to CS8, and the page buffer circuit 92 may store data of an entire page. Only the data stored in the selected sixth cell string CS6 may be decoded as the destination vertex value, and the decoded destination vertex value may be transmitted to the storage controller 11.

In an embodiment, the NVM 90 may include a plurality of memory blocks and may simultaneously apply word line voltages corresponding to data 1010 to the plurality of the memory blocks, thereby reducing the time spent for a search operation on cell strings storing 3 which is the source vertex value SVV.

FIG. 13 is a diagram illustrating a read operation of NVM 130 when a destination vertex value DVV is 0, according to an embodiment.

Referring to FIGS. 1A, 2 and 13, when the destination vertex value DVV received from the storage controller 11 is 0, the NVM 130 may encode the data 0101 from 0 which is a destination vertex value DVV. Then, to search for the cell string corresponding to 0 which is the destination vertex value DVV, the word line voltages corresponding to data 0101, i.e., V_{H}, V_{L}, V_{H}, V_{L}, may be applied to the word lines WL5 to WL8 of the second group, respectively. The memory cells storing data 0 among the second memory cells connected to the word line WL6 may be turned off, and the memory cells storing data 0 among the second memory cells connected to the word line WL8 may be turned off. The second memory cells storing the fifth and sixth destination vertex values D5 and D6 corresponding to 0 which is the destination vertex value DVV may be turned on, whereby current may flow through the fifth and sixth cell strings CS5 and CS6, which may be selected as the cell strings storing the destination vertex value DVV.

The normal read operation may then be performed on the first memory cells included in the selected fifth and sixth cell strings CS5 and CS6. The data stored in the first memory cells included in the selected fifth and sixth cell strings CS5 and CS6 may be read while changing the read voltages applied to the word lines WL1 to WL4 of the first group. The data read from the first memory cells of the fifth cell string CS5 may correspond to the fifth source vertex value S5, e.g., 0, and may be stored in the fifth page buffer PB5. The data read from the first memory cells of the sixth cell string CS6 may correspond to the sixth source vertex value S6, e.g., 0, and may be stored in the sixth page buffer PB6. The fifth and sixth destination vertex values D5 and D6 stored in the fifth and the sixth page buffers PB5 and PB6, respectively, may be transmitted to the storage controller 11.

Hereinafter, the normal read operation on the first memory cells included in the fifth and sixth cell strings CS5 and CS6 may be described in detail. In an embodiment, the sequential read operation may be performed on the first memory cells connected to the word lines WL1 to WL4, respectively, by applying a read voltage sequentially to the words lines WL1 to WL4, and may store data sequentially read from the first memory cells included in the fifth and sixth cell strings CS5 and CS6 into the fifth and sixth page buffers PB5 and PB6, respectively. The data stored in the fifth and sixth page buffers PB5 and PB6, respectively, may be decoded as the source vertex values, and the decoded source vertex values may be transmitted to the storage controller 11. For example, data 0 and 1 may then be read from the first memory cell connected to the word line WL1 by applying a read voltage to the word line WL1, and may be stored in the fifth and sixth page buffers PB5 and PB6, respectively. Data 1 and 0 may then be read from the first memory cell connected to the word line WL2 by applying a read voltage to the word line WL2, and may be stored in the fifth and sixth page buffers PB5 and PB6, respectively. Data 1 and 1 may then be read from the first memory cell connected to the word line WL3 by applying a read voltage to the word line WL3, and may be stored in the fifth and sixth page buffers PB5 and PB6, respectively. Data 0 and 0 may then be read from the first memory cell connected to the word line WL4 by applying a read voltage to the word line WL4, and may be stored in the fifth and sixth page buffers PB5 and PB6, respectively.

Thus, the data 0110 sequentially read from the first memory cells of the fifth cell string CS5 may be decoded into the source vertex value 1, and the data 1010 sequentially read from the first memory cells of the sixth cell string CS6 may be decoded into the sources vertex value 3. For example, the control logic 31 may receive the data 0110 from the fifth page buffer PB5, output the source vertex value 1 by decoding the data 0110, and transmit the source vertex value 1 to the storage controller 11. For example, the control logic 31 may receive the data 1010 from the sixth page buffer PB6, output the source vertex value 3 by decoding the data 1010, and transmit the source vertex value 3 to the storage controller 11.

However, the inventive concept is not limited to the above-described embodiment, and in some embodiments, a read operation may be performed in page units from the first memory cells included in the first to eighth cell strings CS1 to CS8, and the page buffer circuit 132 may store data of an entire page. Only the data stored in the selected fifth and sixth cell strings CS5 and CS6 may be decoded as the source vertex value, and the decoded source vertex value may be transmitted to the storage controller 11.

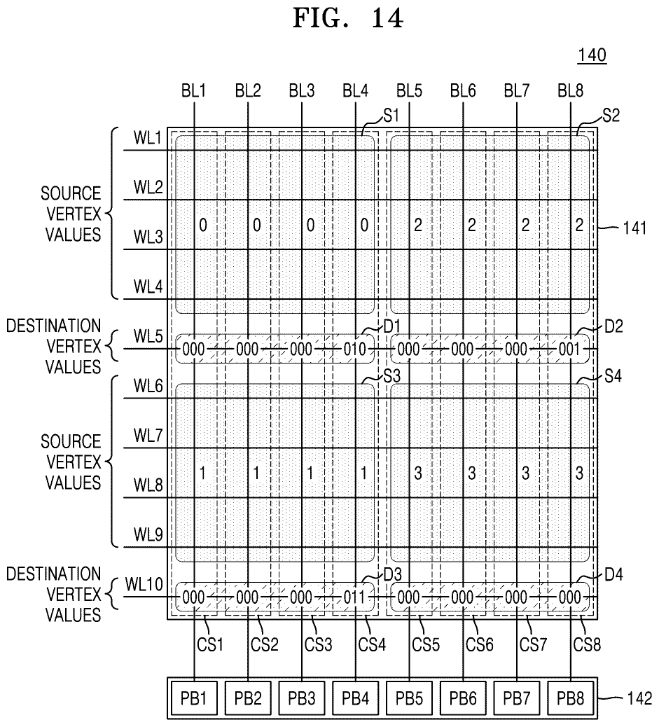

FIG. 14 is a diagram illustrating a memory cell array 141 for storing source vertex values and destination vertex values and a page buffer circuit 142, according to an embodiment.

Referring to FIG. 14, the NVM 140 may include the memory cell array 141 for storing source vertex values and destination vertex values and the page buffer circuit 142. The memory cell array 141 may include a plurality of cell strings CS1 to CS8 connected to a plurality of bit lines BL1 to BL8, respectively, and the page buffer circuit 142 may include a plurality of page buffers PB1 to PB8 connected to a plurality of cell strings CS1 to CS8, respectively.

Each of the first to eighth cell strings CS1 to CS8 may include first to fourth memory cells connected in series. The first memory cells may be connected to the word lines WL1 to WL4 of the first group, respectively, and may store source vertex values. For example, the first memory cells may store data encoded with source vertex values (e.g., data that is an encoded form of the source vertex values). The second memory cell may be connected to the word line WL5 of the second group and may store the destination vertex values. For example, the second memory cells may store the destination vertex values without encoding the destination vertex values. The third memory cells may be connected to word lines WL6 to WL9 of the third group, respectively, and store the source vertex values. For example, the third memory cells may store data encoded with source vertex values (e.g., data that is an encoded form of the source vertex values). The fourth memory cell may be connected to the word line WL10 of the fourth group, and may store the destination vertex values. For example, the fourth memory cells may store the destination vertex values without encoding the destination vertex value.

In an embodiment, the first and third memory cells may include single-level cells (e.g., may be controlled as single-level cells), and the single-level cells may store one bit of data. In an embodiment, the second and fourth memory cells may include multi-level cells (e.g., may be controlled as multi-level cells), and the multi-level cells may store a plurality of bits of data. Cells described herein as single-level cells are configured according to the settings and control of a controller to store one bit, and cells described herein as multi-level cells are configured according to the settings and control of a controller to store more than one bit. For example, the second and fourth memory cells may include triple-level cells (TLCs), although the inventive concept is not limited thereto. For example, the second and fourth memory cells may include quadruple-level cells (QLCs).

The first to fourth cell strings CS1 to CS4 may store the first and third source vertex values S1 and S3 and the first and third destination vertex values D1 and D3. The first source vertex value S1 may be stored in the first memory cells, and may be redundantly stored in the first to fourth cell strings CS1 to CS4. For example, the first memory cells of each of the first to fourth cell strings CS1 to CS4 may store data encoded from 0 which is the first source vertex value S1. The third source vertex value S3 may be stored in the third memory cells, and may be redundantly stored in the first to fourth cell strings CS1 to CS4. For example, the third memory cells of each of the first to fourth cell strings CS1 to CS4 may store data encoded from 1 which is the third source vertex value S3.

The first destination vertex value D1 may be stored in the second memory cells of the first to fourth cell strings CS1 to CS4. For example, the second memory cell of the first cell string CS1 may store 000, the second memory cell of the second cell string CS2 may store 000, the second memory cell of the third memory cell CS3 may store 000, and the second memory cell of the fourth cell string CS4 may store 010, whereby the first destination vertex value D1 may be stored as 000000000010 in the second memory cells. The third destination vertex value D3 may be stored in the fourth memory cells of the first to fourth cell strings CS1 to CS4. For example, the fourth memory cell of the first cell string CS1 may store 000, the fourth memory cell of the second cell string CS2 may store 000, the fourth memory cell of the third cell string CS3 may store 000, and the fourth memory cell of the fourth cell string CS4 may store 011. Accordingly, the third destination vertex value D3 may be stored as 000000000011 in the fourth memory cells.

The fifth to eighth cell strings CS5 to CS8 may store second and fourth source vertex values S2 and S4 and second and fourth destination vertex values D2 and D4. The second source vertex value S2 may be stored in the first memory cells, and may be redundantly stored in the fifth to eighth cell strings CS5 to CS8. For example, the first memory cells of each of the fifth to eighth cell strings CS5 to CS8 may store data encoded from 2 which is the second source vertex value S2. The fourth source vertex value S4 may be stored in the third memory cells, and may be redundantly stored in the fifth to eighth cell strings CS5 to CS8. For example, the third memory cells of each of the fifth to eighth cell strings CS5 to CS8 may store data encoded from 3 which is the fourth source vertex value S4.

The second destination vertex value D2 may be stored in the second memory cells of the fifth to eighth cell strings CS5 to CS8. For example, the second memory cell of the fifth cell string CS5 may store 000, the second memory cell of the sixth cell string CS6 may store 000, the second memory cell of the seventh cell string CS7 may store 000, and the second memory cell of the eighth cell string CS8 may store 001, whereby the second destination vertex value D2 may be stored as 000000000001 in the second memory cells. The fourth destination vertex value D4 may be stored in the fourth memory cells of the fifth to eighth cell strings CS5 to CS8. For example, the fourth memory cell of the fifth cell string CS5 may store 000, the fourth memory cell of the sixth cell string CC6 may store 000, the fourth memory cell of the seventh cell string CS7 may store 000, and the fourth memory cell of the eighth cell string CS8 may store 000. As such, the fourth destination vertex value D4 may be stored as 000000000000 in the fourth memory cells.

In an embodiment, when the source vertex value SVV received from the storage controller 11 is 0, the NVM 140 may encode data 0101 from 0, which is the source vertex value SVV. Then, to search for the cell string corresponding to 0, which is the source vertex value SVV, the word line voltages corresponding to data 0101, i.e., V_{H}, V_{L}, V_{H}, V_{L}, may be applied to the word lines WL1 to WL4 of the first group, respectively, and the pass voltage may be applied to the word lines WL5 to WL10 of the second to the fourth groups. In this case, current may flow through the first to fourth cell strings CS1 to CS4, which may be selected as cell strings storing the source vertex value SVV.

The normal read operation may then be performed on the second memory cells included in the selected fifth to eighth cell strings CS5 to CS8, where the data stored in the second memory cells included in the selected fifth to eighth cell strings CS5 to CS8 may be read by applying a read voltage to the word line WL5 of the second group. The data read from the second memory cells of the fifth to eighth cell strings CS5 to CS8 may correspond to the fourth destination vertex value D4, e.g., 000000000000, and may be stored in the fifth to eighth page buffers PB5 to PB8. The fourth destination vertex value D4 stored in the fifth to eighth page buffers PB5 to PB8 may be transmitted to the storage controller 11.

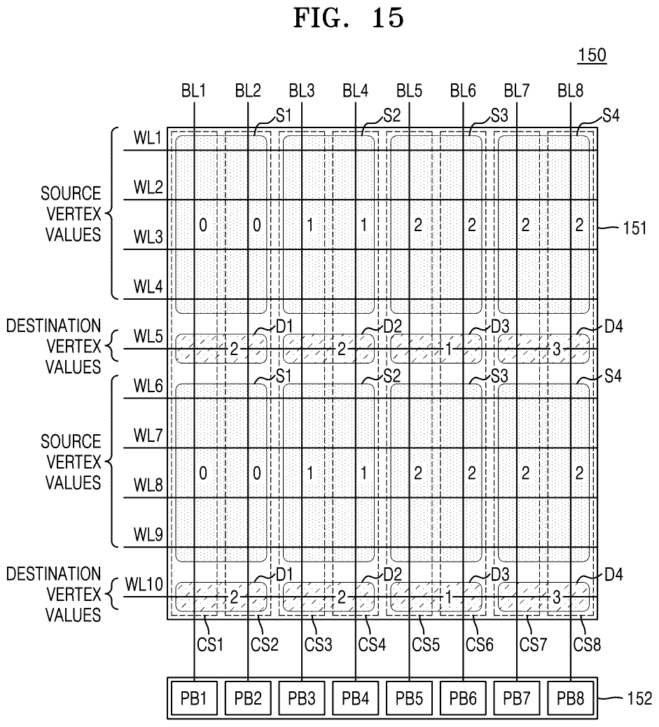

FIG. 15 is a diagram illustrating a memory cell array 151 for storing source vertex values and destination vertex values and a page buffer circuit 152, according to an embodiment.

Referring to FIG. 15, the NVM 150 may include the memory cell array 151 for storing source vertex values and destination vertex values and the page buffer circuit 152. The memory cell array 151 may include a plurality of cell strings CS1 to CS8 connected to a plurality of bit lines BL1 to BL8, respectively, and the page buffer circuit 152 may include a plurality of page buffers PB1 to PB8 connected to a plurality of cell strings CS1 to CS8, respectively.

Referring to FIGS. 2 and 15, each of the first to eighth cell strings CS1 to CS8 may include groups of first to fourth memory cells connected in series. The first memory cells may be connected to the word lines WL1 to WL4 of the first group, respectively, and may store the source vertex value. For example, the first memory cells may store data encoded with the source vertex value. The second memory cells may be connected to the word line WL5 of the second group and may store the destination vertex values. For example, the second memory cells may store the destination vertex value itself without encoding the destination vertex value. The third memory cells may be connected to word lines WL6 to WL9 of the third group, respectively, and store the source vertex values. For example, the third memory cells may store data encoded with the source vertex values. The fourth memory cells may be connected to the word line WL10 of the fourth group, and may store the destination vertex values. For example, the fourth memory cell may store the destination vertex values itself without encoding the destination vertex values.

In an embodiment, the first and third memory cells may include single-level cells, and the single-level cell may store one bit of data. In an embodiment, the second and fourth memory cells may include multi-level cells, and the multi-level cell may store one or more bit of data. For example, the second and fourth memory cells may include TLCs, although the inventive concept is not limited thereto.

The first and second cell strings CS1 and CS2 may store a first source vertex value S1 and a first destination vertex value D1. The first source vertex value S1 may be stored in the first and third memory cells, and may be redundantly stored in the first and second cell strings CS1 and CS2. For example, the first memory cells of each of the first and second cell strings CS1 and CS2 may store data encoded from 0, which is the first source vertex value S1, and the third memory cells of each of the first and second cell strings CS1 and CS2 may store data encoded from 0, which is the first source vertex value S1. The first destination vertex value D1 may be stored in the second and fourth memory cells of the first and second cell strings CS1 and CS2. For example, the second memory cells of the first and second cell strings CS1 and CS2 may store 2, which is the first destination vertex value D1, and the fourth memory cells of the first and second cell strings CS1 and CS2 may store 2, which is the first destination vertex value D1.

The third and fourth cell strings CS3 and CS4 may store a second source vertex value S2 and a second destination vertex value D2. Specifically, the second source vertex value S2 may be stored in the first and third memory cells, and may be redundantly stored in the third and fourth cell strings CS3 and CS4. For example, the first memory cells of each of the third and fourth cell strings CS3 and CS4 may store data encoded from 1, which is the second source vertex value S2, and the third memory cells of each of the third and fourth cell strings CS3 and CS4 may store data encoded from 1, which is the second source vertex value S2. The second destination vertex value D2 may be stored in the second and fourth memory cells of the third and fourth cell strings CS3 and CS4. For example, the second memory cells of the third and fourth cell strings CS3 and CS4 may store 2, which is the second destination vertex value D2, and the fourth memory cells of the third and fourth cell strings CS3 and CS4 may store 2, which is the second destination vertex value D2.

The fifth and sixth cell strings CS5 and CS6 may store a third source vertex value S3 and a third destination vertex value D3. Specifically, the third source vertex value S3 may be stored in the first and third memory cells, and may be redundantly stored in the fifth and sixth cell strings CS5 and CS6. For example, the first memory cells of each of the fifth and sixth cell strings CS5 and CS6 may store data encoded from 2, which is the third source vertex value S3, and the third memory cells of each of the fifth and sixth cell strings CS5 and CS6 may store data encoded from 2, which is the third source vertex value S3. The third destination vertex value D3 may be stored in the second and fourth memory cells of the fifth and sixth cell strings CS5 and CS6. For example, the second memory cells of the fifth and sixth cell strings CS5 and CS6 may store 1, which is the third destination vertex value D3, and the fourth memory cells of the fifth and sixth cell strings CS5 and CS6 may store 1, which is the third destination vertex value D3.

The seventh and eighth cell strings CS7 and CS8 may store a fourth source vertex value S4 and a fourth destination vertex value D4. Specifically, the fourth source vertex value S4 may be stored in the first and third memory cells, and may be redundantly stored in the seventh and eighth cell strings CS7 and CS8. For example, the first memory cells of each of the seventh and eighth cell strings CS7 and CS8 may store data encoded from 2, which is the fourth source vertex value S4, and the third memory cells of each of the seventh and eighth cell strings CS7 and CS8 may store the data encoded from 2, which is the fourth source vertex value S4. The fourth destination vertex value D4 may be stored in the second and fourth memory cells of the seventh and eighth cell strings CS7 and CS8. For example, the second memory cells of the seventh and eighth cell strings CS7 and CS8 may store 3, which is the fourth destination vertex value D4, and the fourth memory cells of the seventh and eighth cell strings CS7 and CS8 may store 3, which is the fourth destination vertex value of D4.

In an embodiment, when the source vertex value SVV received from the storage controller 11 is 0, the NVM 150 may encode data 0101 from 0, which is the source vertex value SVV. Then, to search for the cell string corresponding to 0 which is the source vertex value SVV, the word line voltages corresponding to data 0101, i.e., V_{H}, V_{L}, V_{H}, V_{L}, may be applied to the word lines WL1 to WL4 of the first group and the word lines WL6 to WL9 of the third group, respectively, and the pass voltage may be applied to the word line WL5 of the second group and the words line WL10 of the fourth group. In this case, current may flow through the first and second cell strings CS1 and CS2, which may be selected as cell strings storing the source vertex value SVV.

The normal read operation may then be performed on the second and fourth memory cells included in the selected first and second cell strings CS1 and CS2, where the data stored in the second and fourth memory cells included in the selected first and second cell strings CS1 and CS2 may be read by applying a read voltage to the word line WL5 of the second group and the word line WL10 of the fourth group. The data read from the second and fourth memory cells of the first and second cell strings CS1 and CS2 may correspond to the first destination vertex value D1, e.g., 2, and may be stored in the first and second page buffers PB1 and PB2. The first destination vertex value D1 stored in the first and second page buffers PB1 and PB2 may be transmitted to the storage controller 11.

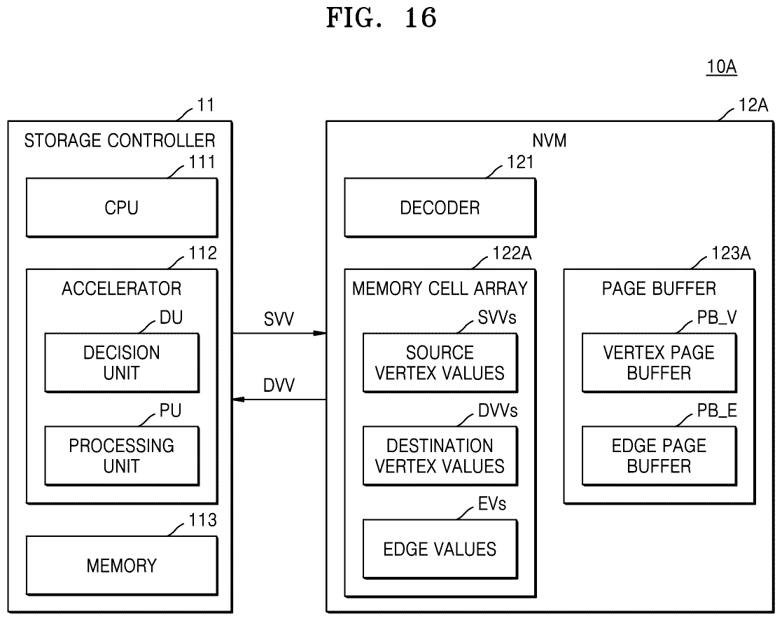

FIG. 16 is a block diagram of a storage device 10A according to an embodiment.

Referring to FIG. 16, the storage device 10A may include a storage controller 11 and NVM 12A, and may correspond to a variation of the storage device 10 of FIG. 1A or the storage device 10′ of FIG. 1B. The details described above with reference to FIGS. 1A to 15 may also be applied to the present embodiment, and redundant description may be omitted. The storage controller 11 may be implemented substantially similarly to the storage controller 11 of FIG. 1A. The NVM 12A may include a decoder 121, a memory cell array 122A, and a page buffer 123A. The memory cell array 122A may store source vertex values SVVs, destination vertex values DVVs, and edge values EVs, wherein each of the edge values EV may correspond to a distance between the source vertex and the destination vertex. The page buffer 123A may include a vertex page buffer PB_V and an edge page buffers PB_E. The vertex page buffer PB_V may store the vertex values read from the memory cell array 122A, and the edge page buffer PB_E may store the edge values read form the memory cell array 122A.

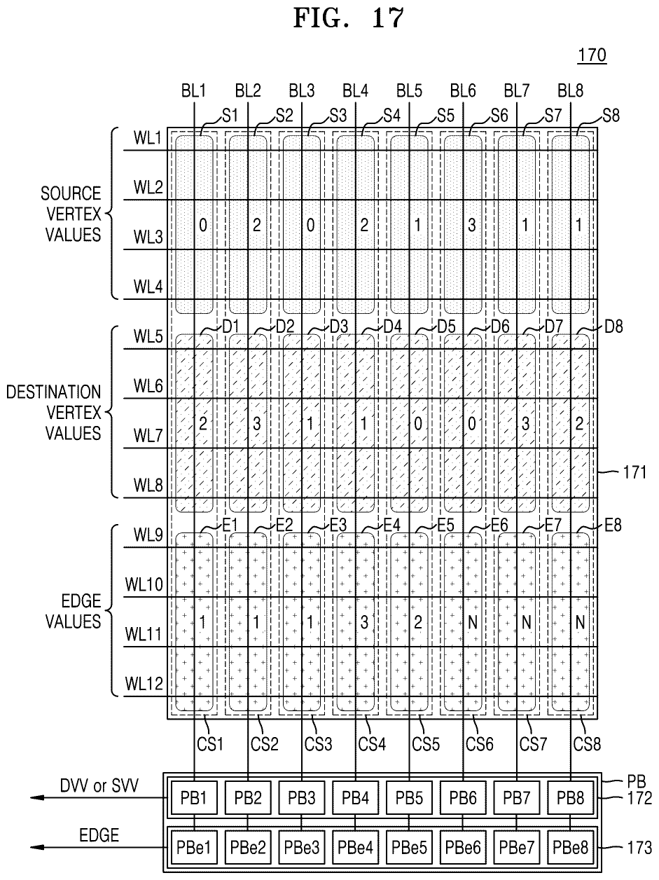

FIG. 17 is a diagram illustrating a memory cell array 171 and a page buffer circuit PB according to an embodiment.

Referring to FIG. 17, the NVM 170 may include a memory cell array 171 for storing source vertex values, destination vertex values, and edge values, and a page buffer circuit PB. The memory cell array 171 may include a plurality of cell strings CS1 to CS8 connected to a plurality of bit lines BL1 to BL8, respectively, and the page buffer circuit PB may include a vertex page buffer circuit 172 and an edge page buffer circuit 173. The vertex page buffer circuit 172 may include a plurality of vertex page buffers PB1 to PB8 connected to the plurality of cell strings CS1 to CS8, respectively. The edge page buffer circuit 173 may include a plurality of edge page buffers PBe1 to PBe8 connected to the plurality of cell strings CS1 to CS8, respectively.

Referring to FIGS. 2 and 17, each of the first to eighth cell strings CS1 to CS8 may include first to third memory cells connected in series. The first memory cells may be connected to the word lines WL1 to WL4 of the first group, respectively, and may store the source vertex value.

The second memory cells may be connected to the word lines WL5 to WL8 of the second group, respectively, and may store the destination vertex value. The third memory cells may be connected to the word lines WL9 to WL12 of the third group, respectively, and may store the edge value. In an embodiment, the first to third memory cells may include single-level cells, wherein each single-level cell is configured to store one bit of data. However, the inventive concept is not limited thereto, and the first to third memory cells may include multi-level cells, which are configured to store two or more bits of data.

For example, the first cell string CS1 may include first memory cells storing data encoded from the first source vertex value S1, second memory cells storing data encoded from the first destination vertex value D1, and third memory cells storing data encoded from the first edge value E1. The first edge value E1 may indicate a distance between the source vertex 0 corresponding to the first source vertex value S1 and the destination vertex 2 corresponding to the first destination vertex value D1. For example, the first edge value E1 may be 1.

Referring to FIGS. 1A and 17, in an embodiment, the NVM 170 may search for the cell string in which the source vertex value SVV received from the storage controller 11 is stored, and may read at least one destination vertex value by performing a read operation on the second memory cells of the found cell string. The read at least one destination vertex value may be stored in a corresponding vertex page buffer. In addition, the NVM 170 may search for the cell string in which the source vertex value SVV received from the storage controller 11 is stored, and may read the at least one edge value by performing a read operation on the third memory cells of the found cell string. The read at least one edge value may be stored in a corresponding edge page buffer.

For example, when the source vertex value SVV received from the storage controller 11 is 0, current may flow through the first and third cell strings CS1 and CS3 in which the data encoded from 0 which is the source vertex value SVV is stored, and 2 and 1 which are the destination vertex values DVVs corresponding to 0 which is the source vertex value SVV may be read by performing a read operation on the second memory cells of the first and third cell strings CS1 and CS3, respectively. 2 and 1 which are the read destination vertex values DVVs may be stored in the first and third vertex page buffers PB1 and PB3, respectively. For example, data stored in the first and third vertex page buffers PB1 and PB3 may be decoded, and may be output as the destination vertex value DVV. In addition, the edge values 1 and 1 corresponding to 0 which is the source vertex value SVV may be read by performing a read operation on the third memory cells of the first and third cell strings CS1 and CS3, respectively. The read edge values 1 and 1 may be stored in the first and third edge page buffers PBe1 and PBe3, respectively. For example, data stored in the first and third edge page buffers PBe1 and PBe3 may be decoded, and may be output as an edge value EDGE.

In an embodiment, the NVM 170 may search for the cell string in which the destination vertex value DVV received from the storage controller 11 is stored, and may read at least one source vertex value by performing a read operation on the first memory cells of the found cell string. The read at least one source vertex value may be stored in a corresponding vertex page buffer. In addition, the NVM 170 may search for the cell string in which the destination vertex value DVV received from the storage controller 11 is stored, and may read the at least one edge value by performing a read operation on the third memory cells of the found cell string. The read at least one edge value may be stored in a corresponding edge page buffer.

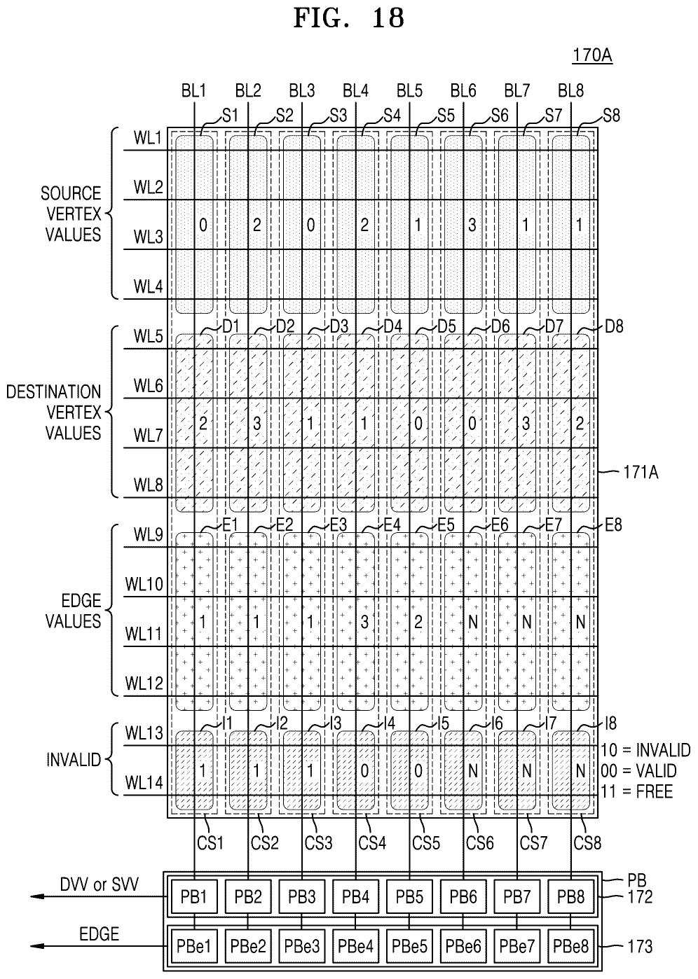

FIG. 18 is a diagram illustrating a memory cell array 171A and a page buffer circuit PB according to an embodiment.

Referring to FIG. 18, the NVM 170A may include a memory cell array 171A for storing source vertex values, destination vertex values, edge values, and invalid information, and a page buffer circuit PB. The NVM 170A may correspond to a variation of the NVM 170 of FIG. 17, and the details described above with reference to FIG. 17 may also be applied to the present embodiment. The invalid information indicates whether the connection relationship between the corresponding source vertex and the destination vertex is invalid. For example, when the destination vertex corresponding to the source vertex is changed, the connection relationship between the source vertex and the destination vertex may be invalid. For example, when the destination vertex corresponding to the source vertex has not changed, the connection relationship between the source vertex and the destination vertex may be valid.

Referring to FIGS. 2 and 18, each of the first to eighth cell strings CS1 to CS8 may include first to fourth memory cells connected in series. The first memory cells may be connected to word lines WL1 to WL4 of the first group, respectively, and may store data encoded from the source vertex value. The second memory cells may be connected to word lines WL5 to WL8 of the second group, respectively, and may store data encoded from the destination vertex value. The third memory cells may be connected to the word lines WL9 to WL12 of the third group, respectively, and may store data encoded from the edge value. The fourth memory cells may be connected to word lines WL13 and WL14 of the fourth group, respectively, and may store data encoded from invalid information. In an embodiment, the first to fourth memory cells may include single-level cells, wherein the single-level cells are configured to store one bit of data. However, the inventive concept is not limited thereto, and the first to third memory cells may be multi-level cells, configured to store two or more bits of data.

For example, the second cell string CS2 may include first memory cells storing data encoded from the second source vertex value S2, second memory cells storing data encoded from the second destination vertex value D2, third memory cells storing data encoded from the second edge value E2, and fourth memory cells storing data encoded from the invalid information 12. The invalid information 12 indicates whether the connection relationship between the second source vertex and the second destination vertex is invalid. For example, when the destination vertex corresponding to the source vertex 2 has changed from vertex 3 to another vertex, the connection relationship between the source vertex 2 and the destination vertex 3 may be invalid, and the fourth memory cells may be programmed to 10 indicating invalid.

For example, the fourth cell string CS4 may include first memory cells storing data encoded from the fourth source vertex value S4, second memory cells storing data encoded form the fourth destination vertex value D4, third memory cells storing data encoded from the fourth edge value E4, and fourth memory cells storing data encoded from the invalid information 14. The invalid information 14 indicates whether the connection relationship between the fourth source vertex and the fourth destination vertex is invalid. For example, when the destination vertex corresponding to source vertex 2 is maintained as 1, the connection relationship between the source vertex 2 and the destination vertex 1 may be valid, and the fourth memory cells may be programmed to 00 indicating valid. Further, an indication of 11 may indicate that a connection relationship between a source vertex and a destination vertex is free (e.g., there is and has been no connection).

Referring to FIGS. 1A and 18, in an embodiment, the NVM 170A may search for the cell string in which the source vertex value SVV received from the storage controller 11 is stored, and may read at least one destination vertex value by performing a read operation on the second memory cells of the found cell string. For example, when the source vertex value SVV is 2, the found cell strings may be the second and fourth cell strings CS2 and CS4. The NVM 170A may check invalid information from the fourth memory cells of the second and fourth cell strings CS2 and CS4, and transmit only the destination vertex value stored in the fourth cell string CS4 to the storage controller 11.

However, the inventive concept is not limited thereto and, in some embodiments, invalid information may be indicated without using fourth memory cells. For example, invalidity may be indicated by programming the first memory cells storing data coded with the source vertex value to 11. For example, invalidity may be indicated by programming the first memory cell storing the source vertex value to a program state higher than the highest program state.

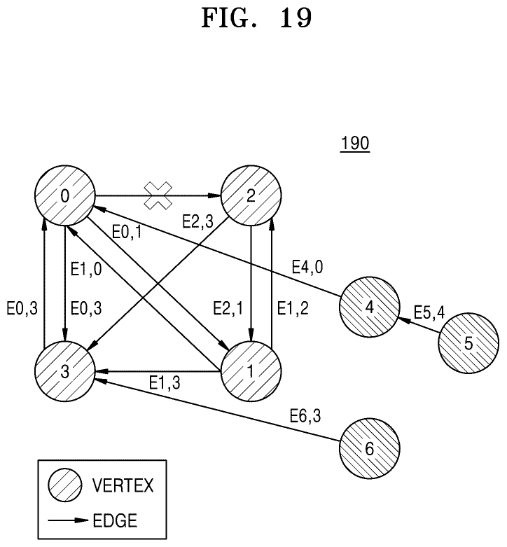

FIG. 19 is an updated graph 190 according to an embodiment.

Referring to FIGS. 2 and 19, the graph 20 of FIG. 2 may be updated to the graph 190 of FIG. 19. Specifically, compared to the graph 20, vertices 4, 5, and 6, and edges E4,0, E5,4, and E6,3 may be added to the graph 190. According to the present embodiment, information on added vertices and added edges may be updated in NVM.

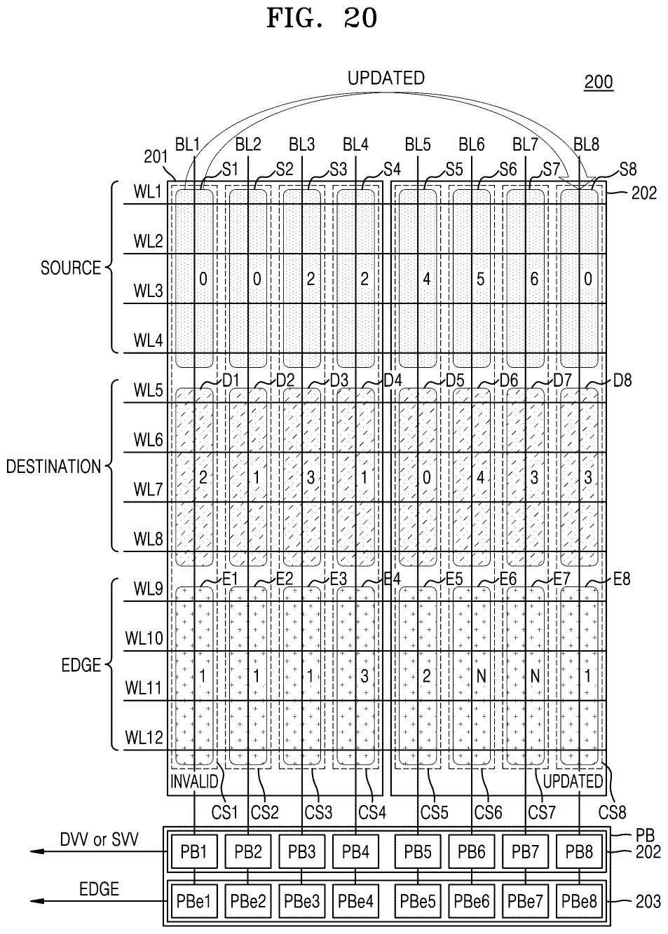

According to an embodiment, FIG. 20 illustrates memory blocks 201 and 202 storing source vertex values and destination vertex values according to the updated graph 190 of FIG. 19, and a page buffer circuit PB.

Referring to FIGS. 19 and 20, the NVM 200 may include the memory block 201 storing the first to fourth source vertices S1 to S4, the first to fourth destination vertices D1 to D4, and the first to fourth edge values E1 to E4, and the memory block 202 storing added fifth to eighth source vertices S5 to S8, added fifth to eighth destination vertices D5 to D8, and fifth to eighth edge values E5 to E8. As such, the updated information in the graph 190 may be stored in the new memory block 202. However, the inventive concept is not limited thereto, and the updated information in the graph 190 may be stored in the existing memory block 201. As one example, when the edge between the source vertex 0 and the destination vertex 2 is changed to an edge between the source vertex 0 and the destination vertex 3, the first cell string CS1 storing the source vertex 0 and destination vertex 2 may be changed to the invalid string, and may be updated to the eighth cell string CS8 storing the source vertex 0 and destination vertex 3.

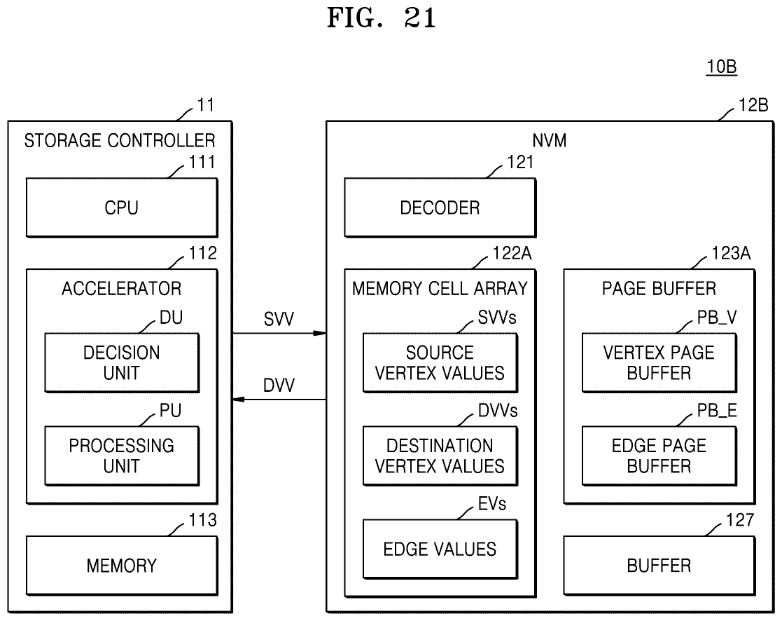

FIG. 21 is a block diagram of a storage device 10B according to an embodiment.

Referring to FIG. 21, the storage device 10B may include a storage controller 11 and NVM 12B, and may correspond to a variation of the storage device 10 of FIG. 1A, the storage device 10′ of FIGS. 1B, and the storage device 10A of FIG. 16. The details described above with reference to FIGS. 1A to 20 may also be applied to the present embodiment, and redundant description may be omitted. The storage controller 11 may be implemented substantially similar to the storage controller 11 of FIG. 1A. The NVM 12B may include a decoder 121, a memory cell array 122A, a page buffer 123A, and a buffer 127. The buffer 127 may store a vertex value output from a vertex page buffer PB_V of the page buffer 123A. Under the control of the storage controller 11, the buffer 127 may provide the stored vertex value to the decoder 121 as a next source vertex or a next destination vertex, which may reduce the amount of data transfer between the storage controller 11 and the NVM 12B.

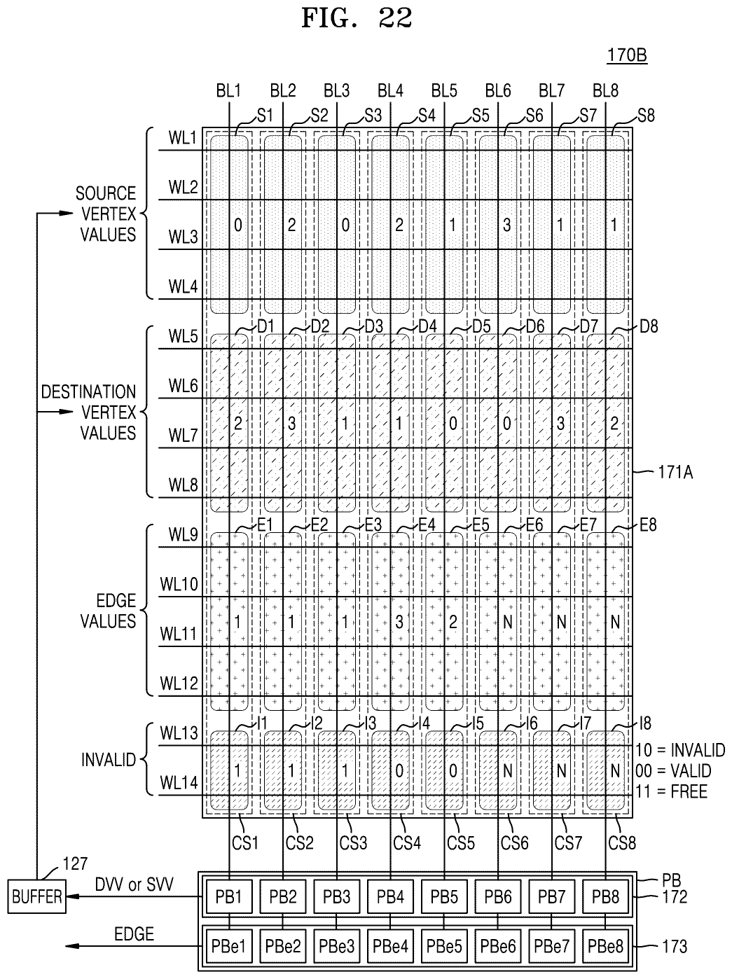

FIG. 22 illustrates a memory cell array 171A, a page buffer circuit PB, and a buffer 127, according to an embodiment.

Referring to FIGS. 21 and 22, the NVM 170B may include a memory cell array 171A storing source vertex values, destination vertex values, edge values, and invalid information. The NVM 170B may correspond to a variation of the NVM 170A of FIG. 18, and redundant description may be omitted. The NVM 170B may further include a buffer 127, compared to the NVM 170A.

The buffer 127 may receive the destination vertex value DVV or the source vertex value SVV from the vertex page buffer circuit 172, and may store the received destination vertex value DVV or source vertex value SVV. Under the control of the storage controller 11, the buffer 127 may provide the stored destination vertex value DVV or source vertex value SVV as a next vertex value.

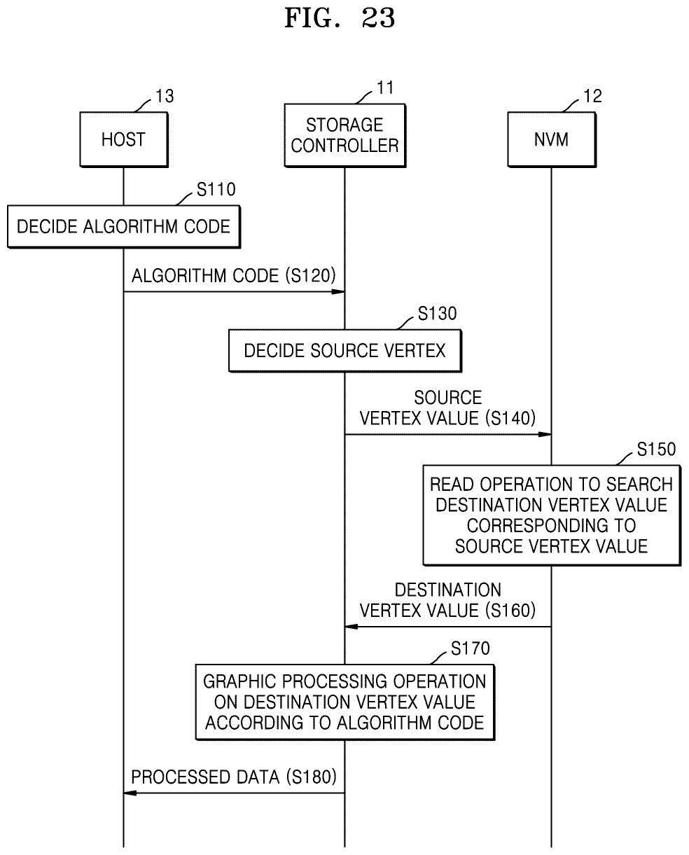

FIG. 23 illustrates a method of operating a host 13, a storage controller 11, and NVM 12 according to an embodiment.

Referring to FIG. 23, in operation S110, the host 13 decides an algorithm code corresponding to a graphic processing operation to be performed in the storage device 10. In operation S120, the host 13 transmits the algorithm code to the storage controller 11. In operation S130, the storage controller 11 decides the source vertex or the source vertex value necessary for the graphic processing operation. In operation S140, the storage controller 11 transfers the source vertex value to the NVM 12. In operation S150, the NVM 12 performs a read operation to search for a destination vertex value corresponding to the source vertex value. In operation S160, the NVM 12 transfers the read destination vertex value to the storage controller 11. In operation S170, the storage controller 11 performs the graphic processing operation on the received destination vertex value, according to the algorithm code. In operation S180, the storage controller 11 transmits the processing data according to the result of the graphic processing operation to the host 13. According to an embodiment, operation S180 may be omitted. The above embodiments may be employed in the NVM 12 for the reading and searching operations.

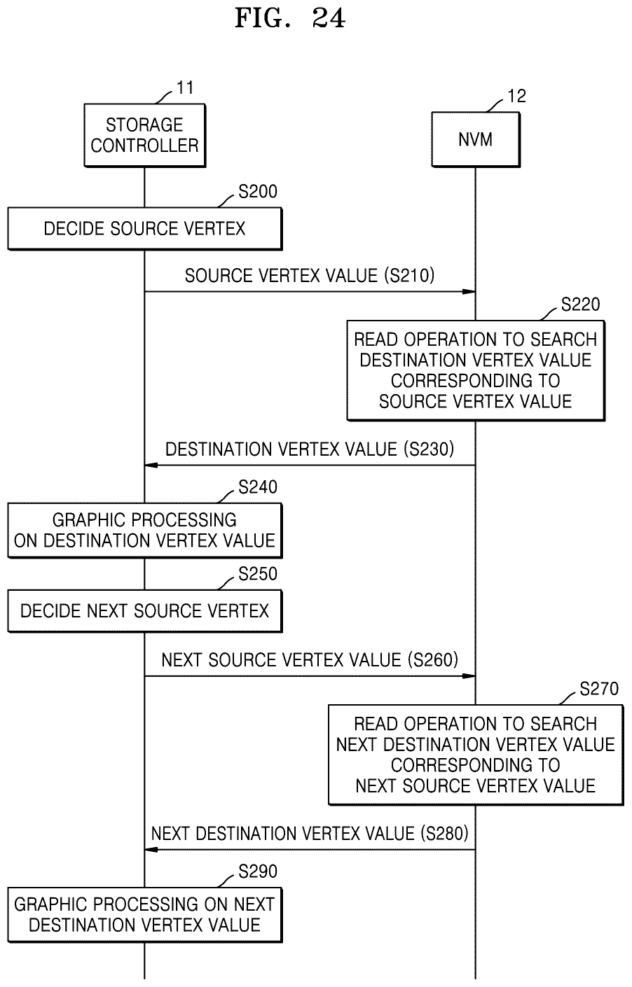

FIG. 24 illustrates a method of operating the storage controller 11 and the NVM 12 according to an embodiment.

Referring to FIG. 24, in operation S200, the storage controller 11 decides the source vertex or the source vertex value necessary for the graphic processing operation. In operation S210, the storage controller 11 transfers the source vertex value to the NVM 12. In operation S220, the NVM 12 performs a read operation to search for a destination vertex value corresponding to the source vertex value. In operation S230, the NVM 12 transfers the read destination vertex value to the storage controller 11. In operation S240, the storage controller 11 performs the graphic processing operation on the received destination vertex value. In operation S250, the storage controller 11 decides the next source vertex or the next source vertex value. In operation S260, the storage controller 11 transmits the next source vertex value to the NVM 12. In operation S270, the NVM 12 performs a read operation to search for a next destination vertex value corresponding to the next source vertex value. In operation S280, the NVM 12 transmits the read next destination vertex value to the storage controller 11. In operation S290, the storage controller 11 performs the graphic processing operation on the received next destination vertex value. The above embodiments may be employed in the NVM 12 for the reading and searching operations.

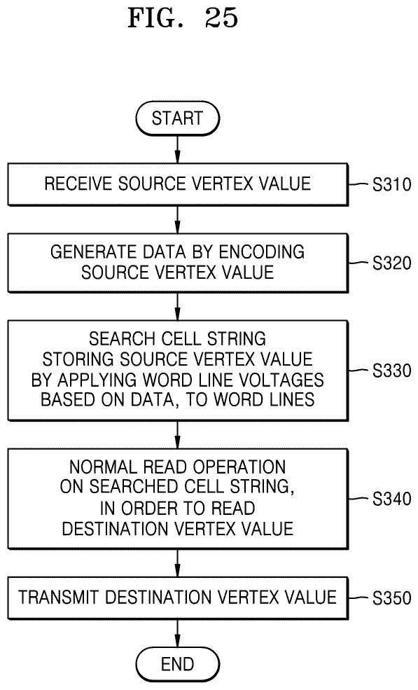

FIG. 25 illustrates a method of operating a non-volatile memory device according to an embodiment;

Referring to FIG. 25, the method of operating the NVM device according to the present embodiment may correspond to a destination vertex value read operation of the NVM, and may be performed, for example, in the NVM 12 of FIG. 1A, the NVM 12A of FIG. 16, or the NVM 12B of FIG. 21. The details described above with reference to FIGS. 1A to 24 may also be applied to the present embodiment.

In operation S310, the NVM 12 receives the source vertex value from the storage controller 11. In operation S320, the NVM 12 generates data by encoding the source vertex value. In operation S330, the NVM 12 searches for the cell string storing the source vertex value, by applying word line voltages according to the data to the word lines of the first group. In operation S340, the NVM 12 performs the normal read operation on the found cell string to read the destination vertex value. In operation S350, the NVM 12 transmits the destination vertex value to the storage controller 11.

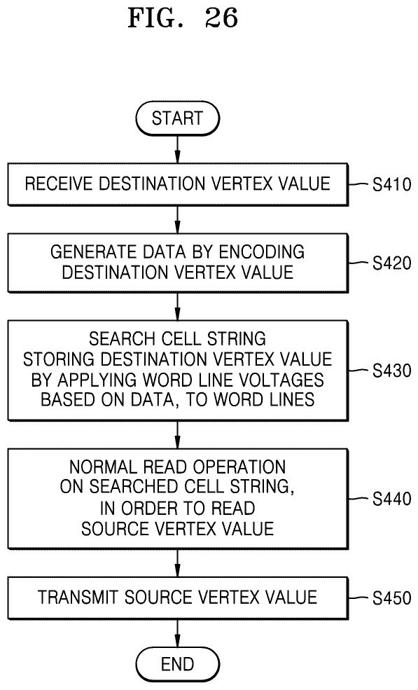

FIG. 26 illustrates a method of operating a non-volatile memory device according to an embodiment; and

Referring to FIG. 26, the method of operating the NVM device according to the present embodiment may correspond to a source vertex value read operation of the NVM, and may be performed, for example, in the NVM 12 of FIG. 1A, the NVM 12A of FIG. 16, or the NVM 12B of FIG. 21. The details described above with reference to FIGS. 1A to 24 may also be applied to the present embodiment.

In operation S410, the NVM 12 receives the destination vertex value from the storage controller 11. In operation S420, the NVM 12 generates data by encoding the destination vertex value. In operation S430, the NVM 12 searches for the cell string storing the destination vertex value, by applying word line voltages according to the data to the word lines of the second group. In operation S440, the NVM 12 performs the normal read operation on the found cell string to read the source vertex value. In operation S450, the NVM 12 transmits the source vertex value to the storage controller 11.

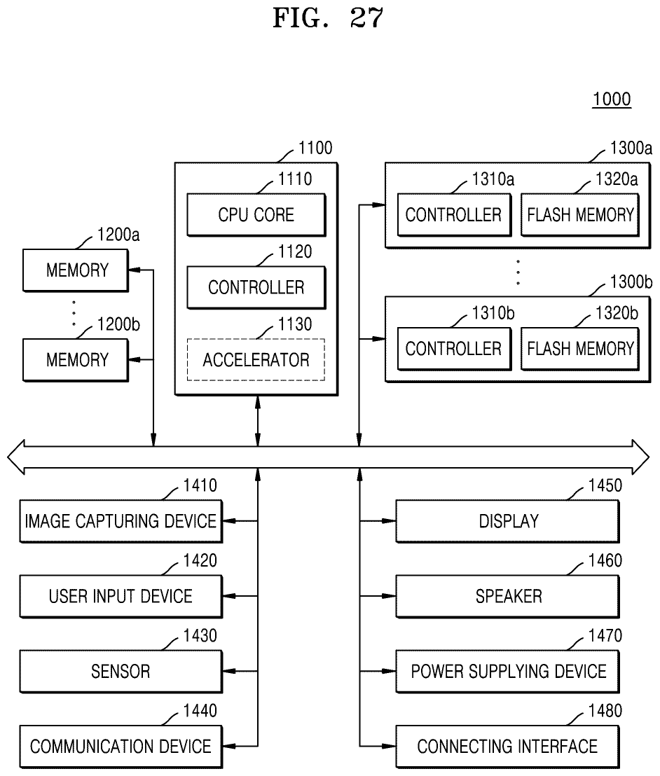

FIG. 27 is a diagram of a system 1000 to which a storage device is applied, according to an embodiment. The system 1000 of FIG. 27 may be a mobile system, such as a portable communication terminal (e.g., a mobile phone), a smartphone, a tablet personal computer (PC), a wearable device, a healthcare device, or an Internet of things (IOT) device. However, the system 1000 of FIG. 27 is not necessarily limited to the mobile system and may be a PC, a laptop computer, a server, a media player, or an automotive device (e.g., a navigation device).

Referring to FIG. 27, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include NVM, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers 1310a and 1310b and NVMs 1320a and 1320b configured to store data via the control of the storage controllers 1310a and 1310b. Some of the data stored, and some of the operations of the NVMs may include the examples discussed above in connection with FIGS. 1A-26. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

While the inventive concept has been particularly shown and described with reference to embodiments thereof, it will be understood that various changes in form and details may be made therein without departing from the spirit and scope of the following claims.

1. A storage device comprising:
non-volatile memory including a plurality of cell strings storing a plurality of source vertex values and a plurality of destination vertex values; and
a storage controller configured to read at least a first destination vertex value corresponding to a first source vertex value among the plurality of source vertex values from the non-volatile memory, and to perform a graphic processing operation based on the read first destination vertex value,
wherein a first cell string among the plurality of cell strings comprises:
a plurality of first memory cells storing the first source vertex value and connected to word lines of a first group of wordlines, respectively; and
at least one second memory cell storing the first destination vertex value and connected to at least one word line of a second group of wordlines.

2. The storage device of claim 1,
wherein the non-volatile memory is configured to:
search for at least one cell string storing the first source vertex value among the plurality of cell strings, by applying word line voltages according to the first source vertex value to the word lines of the first group of wordlines; and
read the first destination vertex value by performing a read operation on the at least one second memory cell when current flows through the first cell string due to the word line voltages.

3. The storage device of claim 1,
wherein a second cell string among the plurality of cell strings comprises:
a plurality of third memory cells storing the first source vertex value and connected to the word lines of the first group or wordlines, respectively; and
at least one fourth memory cell connected to the at least one word line of the second group of wordlines.

4. The storage device of claim 3,
wherein the plurality of first memory cells comprise a plurality of first single-level cells storing data that is an encoded form of the first source vertex value,
the at least one second memory cell comprises a first multi-level cell,
the plurality of third memory cells comprise a plurality of second single-level cells storing data that is an encoded form of the first source vertex value,
the at least one fourth memory cell comprises a second multi-level cell, and each of the first and second multi-level cells stores two or more bits of data.

5. The storage device of claim 3,
wherein the plurality of first memory cells comprise a plurality of first single-level cells storing data that is an encoded form of the first source vertex value,
the at least one second memory cell comprises a plurality of second single-level cells storing data that is an encoded form of the first destination vertex value,
the plurality of third memory cells comprise a plurality of third single-level cells storing data that is an encoded form of the first source vertex value, and
the at least one fourth memory cell comprises a plurality of fourth single-level cells storing data that is an encoded form of a second destination vertex value.

6. The storage device of claim 3,
wherein data stored in the at least one second memory cell and the at least one fourth memory cell correspond to respective destination vertex values.

7. The storage device of claim 3,
further comprising a second destination vertex value, wherein:
the at least one second memory cell stores the first destination vertex value, and
the at least one fourth memory cell stores the second destination vertex value.

8. The storage device of claim 1,
wherein the non-volatile memory further comprises a row decoder configured to apply word line voltages corresponding to the first source vertex value to the word lines of the first group of wordlines, respectively.

9. The storage device of claim 1,
wherein the non-volatile memory further comprises control logic configured to generate data by encoding the first source vertex value.

10. The storage device of claim 9,
wherein the control logic is configured to: receive the first source vertex value from the storage controller;
convert the first source vertex value into a first value; and
generate the data by encoding 0 included in the first value as 01 and encoding 1 included in the first value as 10.

11. The storage device of claim 9,
wherein the control logic is configured to: receive the first source vertex value from the storage controller; and
generate the data by encoding 0 included in the first source vertex value as 01 and encoding 1 included in the first source vertex value as 10.

12. The storage device of claim 1,
wherein the non-volatile memory further comprises a vertex page buffer configured to buffer the first destination vertex value read from the at least one second memory cell.

13. The storage device of claim 12,
wherein the non-volatile memory further comprises a buffer configured to store the first destination vertex value received from the vertex page buffer, and to provide the first destination vertex value as a next vertex value.

14. The storage device of claim 1,
wherein the first cell string further comprises at least one third memory cell storing an edge value corresponding to a distance between two vertices corresponding to the first source vertex value and the first destination vertex value, respectively.

15-16. (canceled)

17. The storage device of claim 1,
wherein the first cell string further comprises at least one third memory cell storing invalid information indicating that a relationship between the first source vertex value stored in the plurality of first memory cells and the first destination vertex value stored in the at least one second memory cell is invalid when the first source vertex value and the first destination vertex value are updated.

18. The storage device of claim 1, configured such that:
when the first source vertex value and the first destination vertex value are updated:
a second cell string among the plurality of cell strings comprises
a plurality of memory cells storing the updated first source vertex value, and
at least one memory cell storing the updated first destination vertex value.

19. The storage device of claim 1,
wherein the storage controller comprises an accelerator configured to receive a first algorithm code among a plurality of algorithm codes from a host, and to perform the graphic processing operation on first destination vertex value according to the first algorithm code.

20-21. (canceled)

22. A storage device comprising: non-volatile memory including a plurality of cell strings storing a plurality of source vertex values and a plurality of destination vertex values; and
a storage controller configured to read at least a first source vertex value corresponding to a first destination vertex value among the plurality of destination vertex values from the non-volatile memory, and to perform a graphic processing operation based on the read first source vertex value;
wherein a first cell string among the plurality of cell strings comprises:
a plurality of first memory cells storing the first destination vertex value and connected to word lines of a first group of wordlines, respectively; and
at least one second memory cell storing the first source vertex value and connected to at least one word line of a second group of wordlines.

23. The storage device of claim 22, wherein a second cell string among the plurality of cell strings comprises:
a plurality of third memory cells storing the first destination vertex value and connected to the word lines of the first group of wordlines, respectively; and
at least one fourth memory cell connected to the at least one word line of the second group of wordlines.

24-25. (canceled)

26. A non-volatile memory device comprising: control logic configured to generate data by encoding a first source vertex value received from a controller;
a row decoder configured to apply word line voltages according to the first source vertex value to word lines of a first group, respectively; and
a memory cell array including a plurality of cell strings storing a plurality of source vertex values and a plurality of destination vertex values;
wherein a first cell string among the plurality of cell strings comprises:
a plurality of first memory cells storing the first source vertex value and connected to the word lines of the first group, respectively, and
at least one second memory cell storing a first destination vertex value among at least one destination vertex value, and
when current flows through the first cell string due to the word line voltages, the non-volatile memory device reads the first destination vertex value through a read operation on the at least one second memory cell.

27-35. (canceled)
